(19) United States
(12) Patent Application Publication
(10) Pub. No.: US 2026/0320254 A1
(43) Pub. Date: Oct. 15, 2026

(54) FORECASTING RESOURCE PRODUCTION USING TIME-SERIES DATA

(71) Applicant: Schlumberger Technology Corporation, Sugar Land, TX (US)

(72) Inventor: Fatima Ghanduri, Tripoli (LY)

(21) Appl. No.: 19/174,538

(22) Filed: Apr. 9, 2025

(51) Int. Cl. G06F 30/27; G06F 17/18

(52) U.S. Cl. CPC G06F 30/27; G06F 17/18

(57) ABSTRACT

This application relates to forecasting resource production using time-series data. Simulations of select features of the data may be applied using repeated random sampling. One of a set of models may be applied to the data associated with a time period. The model for each time period may be dependent on an amount of change of the resource production from the previous time period. Regimes associated with the amount of change, such as spike, dip, and normal, may be used to determine the model. A relative importance of each feature of the time-series data may be determined, and a Monte Carlo simulation may be applied to the portion of the time-series data associated with the features having the highest relative importances. An uncertainty of a resource production forecast may include an unweighted contribution, a weighted contribution, and a dynamic contribution associated with the features.

### BACKGROUND

Forecasting petroleum and other resource production is a critical component of optimizing energy projects, particularly in offshore and complex production environments. For example, accurate predictions of oil production rates enable operators to manage resources effectively, enhance operational efficiency, and mitigate financial risks. In the context of optimizing offshore, onshore, and energy projects, the integration of predictive modeling, economic assessments, and risk management with AI-driven methodologies has emerged as a transformative approach, enabling more informed and strategic decision-making.

Traditional forecasting methods, such as Hubbert's curve and multi-cyclic Gaussian models, have been widely used for long-term production predictions. While these models are effective for broad-scale forecasting, they fail to address the dynamic complexities of daily production performance, e.g., for an oil well. These conventional methods primarily rely on static inputs, such as reservoir characteristics and well-design parameters, and assume fixed growth and decline rates. Consequently, they are limited in their ability to adapt to real-time operational changes, fail to capture the probabilistic nature of production, and do not provide uncertainty metrics that are useful for comprehensive risk management in resource production.

Uncertainty quantification in resource production forecasting is desired for onshore projects and, particularly, offshore projects, where high operational costs and environmental risks amplify the importance of accurate and reliable predictions. Reservoir heterogeneity, fluctuating operational conditions, and external factors such as market volatility contribute to significant variability in production rates. Without explicitly quantifying this uncertainty, decision-makers risk overcommitting resources, underestimating risks, and failing to account for worst-case scenarios.

### SUMMARY

In response to these and other challenges, embodiments are provided that integrate feature importance determination (e.g., using Shapley Additive explanations (SHAP)) and Monte Carlo simulations to enhance production forecasting (e.g., for a well) in a timely manner (e.g., daily, hourly, or even for often) using accurate up-to-date production performance data (e.g., daily well-performance data). By combining these techniques, interpretability and robust uncertainty quantification may be provided, making it highly applicable for optimizing resource production, such as onshore or offshore energy projects.

In some embodiments, different models are applied to time-series data of different time periods based on the amount of change of the resource production from one time period to the next. This allows specific models to be used that handle different types of changes better than other models, which allows for more accurate overall resource production forecasts.

The integration of artificial intelligence (AI)-driven predictive modeling with risk management techniques is especially beneficial for addressing challenges faced by onshore, offshore and energy projects. Examples discussed herein leverage AI for interpretability and insight. Feature importance analysis (e.g., SHAP-based) provides an interpretable framework for understanding drivers of production variability, empowering operators to make informed decisions based on actionable insights. Examples discussed herein may be used to perform economic or other assessments through uncertainty quantification. The Monte Carlo simulation framework may be used to predict production rates and quantify a range of potential outcomes, which may enable robust economic and other assessments under various scenarios. Examples discussed herein may therefore enhance risk management capabilities. By explicitly modeling uncertainty in production forecasts, decision-makers may be equipped with tools to assess and mitigate risks more effectively, improving the reliability of resource production plans (e.g., onshore or offshore project plans) and budgets.

In some embodiments, a computer-implemented method may be provided for obtaining a set of time-series data associated with production of a resource, the set of time-series data including a plurality of features, the set of time-series data including subsets of data respectively associated with a plurality of time periods; applying, by one or more computers, a feature importance algorithm to the set of time-series data to determine a relevance of each feature of the plurality of features to a production forecast of the resource and to generate a subset of features that consists of features of the plurality of features determined to have relevances that are greater than relevances determined for other features of the plurality of features; and applying, by the one or more computers, a Monte Carlo simulation to a portion of the set of time-series data associated with the subset of features to determine a production rate forecast of the resource and an associated uncertainty.

In some embodiments, a computer-implemented method may be provided for obtaining a set of time-series data associated with production of a resource, the set of time-series data including subsets of data respectively associated with a plurality of time periods; determining, by one or more computers for each time period of the plurality of time periods, an amount of change of the production of the resource with respect to an adjacent previous time period of the plurality of time periods; applying, by the one or more computers for each time period, one of a set of trained models to the respective subset of data associated with the time period to determine a production rate forecast of the resource associated with the time period, wherein the one of the set of trained models that is applied to the respective subset of data is determined by the one or more computers based on the amount of change of the production of the resource associated with the time period; determining, by the one or more computers, an overall production rate forecast of the resource based on the production rate forecasts of the resource associated with each time period.

In some embodiments, a computer-implemented method may be provided for obtaining a set of time-series data associated with production of a resource, the set of time-series data including a plurality of features, and the set of time-series data including subsets of data respectively associated with a plurality of time periods; applying, by one or more computers, a feature importance algorithm to the set of time-series data to determine a relative importance of each feature of the set of features to a production forecast of the resource; determining, by the one or more computers, for each time period of the plurality of time periods, an amount of change of the production of the resource with respect to an adjacent previous time period of the plurality of time periods; determining, by the one or more computers for each time period, a production rate forecast of the resource associated with the time period by applying a Monte Carlo simulation to a portion of the respective subset of data associated with a subset of features using one of a set of trained models, wherein the subset of features is a subset of the plurality of features determined to have relative importances that are greater than relevances determined for other features of the plurality of features, and wherein the one of the set of trained models that is used for the time period is determined by the one or more computers based on the amount of change of the production of the resource associated with the time period; and determining, by the one or more computers, an overall production rate forecast of the resource and an overall uncertainty based on the production rate forecasts of the resource associated with each time period.

In some embodiments, a computer-implemented method may be provided for obtaining a set of time-series data associated with production of a resource, the time-series data including, for each time period associated with the set of time-series data, values of features associated with the production of the resource; determining, by one or more computers for each time period, a production rate forecast of the resource and a variance of each feature based on the values of the features associated with the time period; determining, by the one or more computers, an overall production rate forecast of the resource based on the production rate forecasts of the resource associated with each time period; determining, by the one or more computers, an unweighted contribution associated with one or more of the features associated with the set of time-series data; determining, by the one or more computers, a weighted contribution associated with the one or more features; determining, by the one or more computers, a dynamic contribution associated with the one or more features based on the determined variances; and determining, by the one or more computers, a dynamic contribution associated with the one or more features based on the determined variances.

This summary is provided to introduce a selection of concepts that are further described below in the detailed description. This summary is not intended to identify key or essential features of the claimed subject matter, nor is it intended to be used as an aid in limiting the scope of the claimed subject matter. Additional features and advantages of embodiments of the disclosure will be set forth in the description which follows, and in part will be obvious from the description, or may be learned by the practice of such embodiments.

### BRIEF DESCRIPTION OF THE DRAWINGS

In order to describe the manner in which the above-recited and other features of the disclosure can be obtained, a more particular description will be rendered by reference to specific implementations thereof which are illustrated in the appended drawings. For better understanding, the like elements have been designated by like reference numbers throughout the various accompanying figures. While some of the drawings may be schematic or exaggerated representations of concepts, at least some of the drawings may be drawn to scale. Understanding that the drawings depict some example implementations, the implementations will be described and explained with additional specificity and detail using the accompanying drawings in which:

FIG. 1 is a block diagram illustrating a method that supports forecasting resource production using time-series data, according to at least one embodiment;

FIG. 2 is a block diagram illustrating a method and data flow that supports forecasting resource production using time-series data, according to at least one embodiment;

FIG. 3 is a block diagram illustrating how a feature importance algorithm is applied to a set of time-series data, according to at least one embodiment;

FIG. 4 is a block diagram illustrating how a Monte Carlo simulation is applied to a set of time-series data associated with a subset of its features, according to at least one embodiment.

FIG. 5 depicts a series of acts in a computer-implemented method for a series of acts in a computer-implemented method for determining an overall uncertainty associated with a resource production forecast, according to at least one embodiment.

FIG. 6 is a block diagram illustrating a method of forecasting resource production using time-series data, according to at least one embodiment;

FIG. 7 depicts a series of acts in a computer-implemented method for determining a production rate forecast of a resource according to at least one embodiment;

FIG. 8 depicts a series of acts in a computer-implemented method for determining a production rate forecast of a resource according to at least one embodiment;

FIGS. 9A and 9B depict a series of acts in a computer-implemented method for determining a production rate forecast of a resource according to at least one embodiment; and

FIG. 10 depicts a series of acts in a computer-implemented method for determining a production rate forecast of a resource according to at least one embodiment;

FIG. 11 illustrates certain components that may be included within a computer system, according to at least one embodiment; and

FIG. 12 depicts a series of acts in a computer-implemented method for determining a production rate forecast of a resource according to at least one embodiment.

### DETAILED DESCRIPTION

This disclosure generally relates to forecasting resource production by applying simulations of select features using repeated random sampling. Feature importance determination and Monte Carlo simulations are integrated, offering a dynamic, interpretable, and probabilistic approach to production forecasting. The feature importance determination enables the identification of key drivers of production variability from time-series data, offering feature importance insights that adapt to temporal changes. These insights are incorporated into Monte Carlo simulations of the time-series data, to model the probabilistic range of production outcomes, providing actionable forecasts and robust risk assessments. SHAP may be used for the feature importance determination. More accurate uncertainties may be determined based on the Monte Carlo simulations and the SHAP information.

As will be discussed in further detail below, the present disclosure includes a number of practical applications having features described herein that provide benefits and/or solve problems associated with petroleum production forecasting. Some example benefits are discussed herein in connection with various features and functionalities provided by a production forecasting system implemented on one or more computing devices. It will be appreciated that benefits explicitly discussed in connection with one or more embodiments described herein are provided by way of example and are not intended to be an exhaustive list of all possible benefits of the transition detection system.

For example, the resource production forecasting system described herein may allow for more enhanced decision-making capabilities be used to provide more improved predictive accuracy and for risk management in volatile production phases. By explicitly modeling the uncertainty in production forecasts, the resource production forecasting system herein allows for more informed and risk-aware decision-making, which is critical, for example, for offshore energy projects where financial and operational risks are high. By incorporating regime-specific modeling, the resource production forecasting system may further improve predictive accuracy.

Further, the resource production forecasting system may be implemented with certain important resources. For example, it may be used to forecast the production of carbon dioxide (e.g., from a coal power plant or from steel production) for sequestration. Carbon sequestration is the process of capturing and storing atmospheric carbon dioxide in solid or liquid form. The carbon dioxide may be permanently stored in gaseous form, such as in gaseous storage in deep geological formations (including saline formations and exhausted gas fields), or in solid form, such as in solid storage by reaction of carbon dioxide with metal oxides to produce stable carbonates. Accurately forecasting the production of carbon dioxide may help to determine a size needed for storage locations as well as transportation needed to move the carbon dioxide to the storage locations. Storing carbon dioxide is increasingly important because carbon dioxide emissions are warming the Earth's climate in ways not seen in millions of years.

Further, the resource production forecasting system may be implemented to predict workovers. It may identify when resource production (e.g., of a well) begins to deviate from expected performance, signaling the desire for intervention. By analyzing the production trends and forecasting future behaviors, the resource production forecasting system may help to determine optimal timing for workover operations, reducing downtime and improving overall productivity. This predictive capability may allow for interventions to be made at the right time, minimizing costs and maximizing recovery.

Further, the resource production forecasting system may be implemented to predict the lifetime of a well and its future production value. By tracking and analyzing historical production data, the resource production forecasting system may be used to estimate when a well will reach its peak and when production will start to decline, providing insights into its remaining life.

Further, the resource production forecasting system may be used to capture daily production fluctuations, allowing for real-time adjustments and more accurate forecasting. Unlike traditional reservoir engineering models that focus on long-term trends, the resource production forecasting system may handle daily variability, making it more responsive to operational changes. This capability may help to manage well performance, detect issues early, and optimize day-to-day operations. Daily forecasts may allow for better resource management and operational efficiency. They may allow for more timely decisions on resource allocation, maintenance, and production optimization, minimizing risks and reducing costs associated with over or underproduction.

The term “machine-learning model” refers to a computer model or computer representation that may be trained (e.g., optimized) based on inputs to approximate unknown functions. For instance, a machine-learning model may include, but is not limited to, a neural network (e.g., a convolutional neural network (CNN), LSTM, graph neural network, or deep learning model), a decision tree (e.g., a gradient-boosted decision tree), a linear regression model, a logistic regression model, Dirichlet allocation (LDA) model, multi-arm bandit model, random forest model, support vector machine (SVM) model, or a combination of these models.

A time series is a data set that tracks one or more samples over time. It allows one to see what factors influence certain variables from one period of time to the next. Time-series analysis can be useful to see how a given variable changes over time. But time series is a unique type of problem in machine learning where the time component plays a role in the model predictions. In time series, observations are dependent on adjacent observations, which violates the assumption followed by most conventional machine learning models that observations are independent to each other. Time-series regression differentiates from other regression models, because of its assumption that data correlated over time and the outcomes from previous periods can be used for predicting the outcomes in the subsequent periods.

For the purposes of this application, “a set of time-series data” includes data associated with a target sample and multiple features associated with the target sample over multiple time periods. This data may also be referred to as “a set of time-series data associated with the target sample.” For example, in at least one embodiment, the target sample is a resource production, the multiple features are features associated with the resource production (e.g., average downhole pressure, average downhole temperature, etc.) and the set of time-series data associated with the resource production includes data associated with the resource production and associated features over multiple time periods. Data associated with a time period of the multiple time periods may be referred to herein as a subset of data of the set of time-series data.

SHAP is used to explain individual predictions. The goal of SHAP is to explain the prediction of an instance x by computing the contribution of each feature to the prediction. Using SHAP, a prediction can be explained by assuming that each feature value of the instance is a “player” in a game where the prediction is the payout. Shapley values—a method from coalitional game theory—tells us how to fairly distribute the “payout” among the features. As such, SHAP may be used as a feature importance algorithm. The Shapley value is the average marginal contribution of a feature value across all possible coalitions (sets) of features. The SHAP method computes optimal Shapley values. SHAP is represented as an additive feature attribution method, a linear model. For a given time period, the SHAP value for a feature i is defined as:

$${ϕ}_{i} = {\sum }_{S ⊆ F \{ i \}} \frac{\vert S \vert ! ( \vert F \vert - \vert S \vert - 1 ) !}{\vert F \vert !} [ v ( S ⋃ \{ i \} ) - v ( S ) ]$$

Where F is the set of all features, S is a subset of features exclusive of i, and v (S) is the model output using only feature S. The SHAP values are aggregated across the time-series data to capture feature importance dynamics over time.

These values may be visualized to interpret the impact of individual features on the instance x, facilitating the identification of key drivers of production variability. For example, SHAP can generate a list of the features with a score that represents a relative importance or relevance to the model. That way, the relative importance or relevance of the features may be compared with each other and understood (explained). In at least one embodiment, SHAP is used to determine the relative importance or relevance of features used in determining resource production forecasts. For the purposes of this application, the terms “importance,” “relevance,” “relative importance,” and “relative relevance” may be used interchangeably.

A Monte Carlo simulation is a way to model the probability of different outcomes in a process that cannot easily be predicted due to the intervention of random variables. It is a technique used to understand the impact of risk and uncertainty in prediction and forecasting models. In a Monte Carlo simulation, repeated random sampling is used to predict possible outcomes of an uncertain event (e.g., a resource production forecast). For example, multiple values may be assigned to an uncertain variable (e.g., a feature) to achieve multiple results (e.g., of the resource production forecast) and then the results may be averaged to obtain an estimate or forecast. A Monte Carlo simulation takes the variable that has uncertainty and assigns it a random value. The model is then run, and a result is provided. This process is repeated again and again while assigning many different values to the variable in question. Once the simulation is complete, the results are averaged to arrive at an estimate. A probability or uncertainty value and range may also be determined based on a distribution of the individual results of the Monte Carlo simulation. For example, the probability or uncertainty may be determined based on a mean, a standard deviation, confidence intervals, or other comparable computation of the individual results of the Monte Carlo simulation. In at least one embodiment, Monte Carlo simulations are used to determine probabilistic distributions and uncertainty ranges of production rate forecasts.

Additional terms are defined throughout the disclosure in connection with various examples and contexts.

The examples discussed herein are generally directed to resource production in the petroleum industry, such as oil production of onshore and offshore energy projects. However, the concepts and examples discussed herein may also be applied to the production of other types of resources. These resources may include, but are not limited to, other natural liquids (e.g., petroleum) or gases (e.g., natural gas, helium). They may also include resources that are mined (e.g., coal, lithium), manufactured (e.g., steel, concrete), or created as a result of other actions (e.g., carbon dioxide from coal plants, network traffic from computer communications). The production may also apply to other types of resources, such as the production of carbon credits and carbon dioxide sequestration. These lists are not exhaustive and may include still other types of resources and production types.

Forecasting resource production (e.g., petroleum production) plays an important role in optimizing projects, especially those where the integration of predictive modeling, economic assessments, and risk management is crucial. For example, offshore energy projects face unique challenges due to high operational costs, environmental uncertainties, and the dynamic nature of production systems. Traditional approaches, while foundational, often lack the adaptability and precision required for modern project optimization. For example, the increasing complexity of offshore operations necessitates data-driven methodologies that can seamlessly integrate predictive analytics, risk quantification, and actionable insights, often on a daily basis.

Traditional forecasting methods such as Hubbert's curve and multi-cyclic Gaussian models have historically been employed to estimate oil production. These models rely on assumptions of fixed growth and decline patterns based on reservoir depletion dynamics and are effective for capturing long-term trends. However, they are inherently limited in their adaptability to real-time data, making them insufficient for the dynamic and high-variability conditions often encountered in onshore and offshore energy projects. Additionally, these models lack the ability to quantify uncertainty, providing deterministic forecasts that fail to capture the probabilistic nature of production, severely limiting their use for financial and operational risk management.

Numerical reservoir simulations, while more detailed, face challenges in handling large-scale datasets and are computationally intensive. These simulations rely heavily on the accuracy of input parameters and are often impractical for real-time optimization in onshore and offshore projects, where operational adjustments are frequent and decision-making timelines are short.

Additional details will now be provided regarding systems described herein in relation to illustrative figures portraying example implementations.

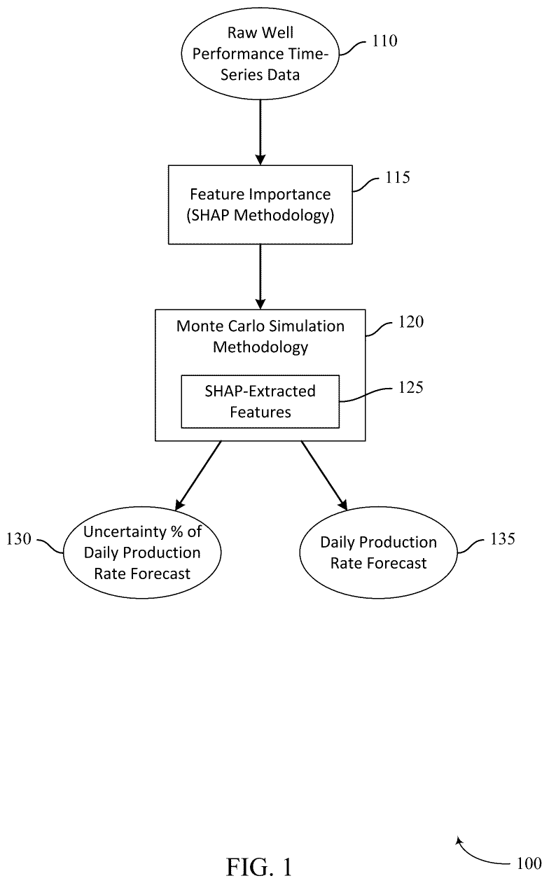

FIG. 1 is a block diagram illustrating a method 100 that supports forecasting resource production using time-series data, according to at least one embodiment. The method 100 builds on advancements in machine learning (ML) and probabilistic modeling while addressing limitations of existing approaches. The framework integrates feature importance analysis of a set of time-series data (e.g., using SHAP) and probabilistic forecasting using Monte Carlo simulations. This two-layered approach addresses both interpretability and uncertainty quantification, enabling robust and risk-aware decision-making for onshore, offshore and energy projects.

The method 100, as well as any other method discussed herein, may be performed a single time or multiple times. It may be performed on an as-desired basis, or on a reoccurring schedule. For example, the method 100 may be performed monthly, weekly, daily, hourly, once per minute, once per second, etc., or at any other interval.

At block 115, a feature importance algorithm is applied to time-series data 110 associated with production of a resource. The time-series data includes a plurality of features. The algorithm determines a relative importance or relevance associated with each feature of the data to a production forecast. Based thereon, the feature importance algorithm generates a list (or subset) of features that includes the most relevant features. In at least one embodiment, the feature importance algorithm is a SHAP algorithm. Other feature importance algorithms can also be used, such as a principal component analysis. Details regarding the application of SHAP to the time-series data is discussed herein. The data may be raw well performance data, as depicted, or may be other type of time-series data. The time-series data may include data for any number of time periods that together cover a total amount of time. For example, the time-series data may include hourly data covering a 24-hour day. This may be desired, for example, if the method 100 is being performed on a daily basis, using raw well performance data.

At block 120, a Monte Carlo simulation is applied to a portion of the time-series data associated with the subset of features (determined at block 115) over the total time period to determine a production rate forecast 135 and an associated uncertainty 130 using information 125 obtained from the SHAP application. In the depicted embodiment, the method 100 is performed daily so that the production rate forecast and associated uncertainty is a daily forecast. Details regarding the application of Monte Carlo simulation to the time-series data is discussed herein.

Integrating feature importance identification, such as SHAP, and Monte Carlo offers a dynamic, interpretable, and probabilistic approach to production forecasting. It also represents a significant advancement over prior methodologies by combining interpretability, adaptability, and uncertainty quantification into a unified solution. For example, SHAP enables the identification of key drivers of production variability from time-series data, offering feature importance insights that adapt to temporal changes. These insights are then incorporated into Monte Carlo simulations, which model the probabilistic range of production outcomes, providing actionable forecasts and robust risk assessments.

This approach addresses the complexities of resource production systems, such as onshore and offshore production systems, making it a robust tool for optimizing energy projects in a high-risk, data-driven industry. It also aligns with goals of optimizing resource projects (e.g., onshore, offshore and energy resources) by enhancing predictive accuracy through feature importance analysis that dynamically adapts to daily production data, providing uncertainty quantification to enable risk-aware economic and operational decision-making and bridging the gap between predictive modeling, economic assessments, and risk management, leading to a comprehensive approach to offshore project optimization.

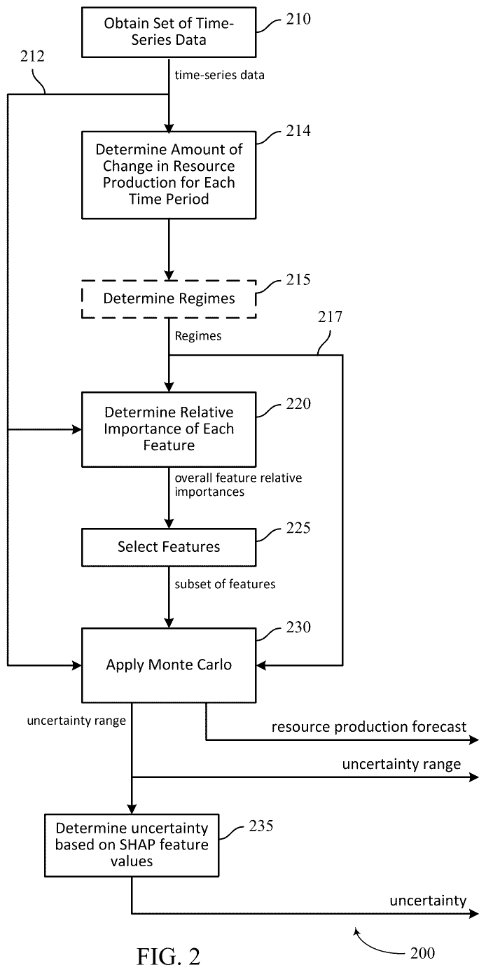

FIG. 2 is a block diagram illustrating a method 200 and data flow that supports forecasting resource production using time-series data, according to at least one embodiment. Using method 200, a resource production forecast, such as an oil or a gas production forecast, may be determined along with a corresponding uncertainty. Other types of resource production forecasts and corresponding uncertainties may also be determined using method 200. Although method 200 is presented as applying to oil production forecasts, it can also apply to other types of resource production forecasting, as discussed herein.

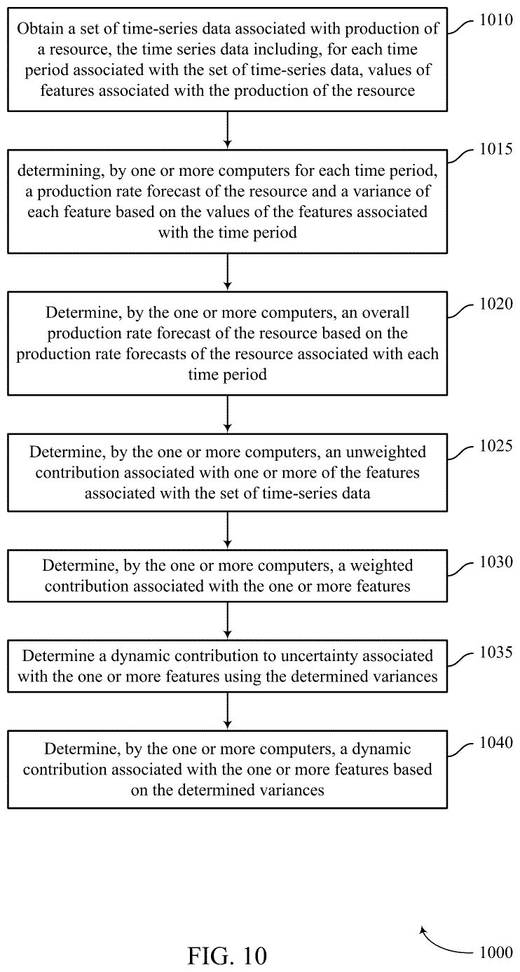

Alternative implementations may omit, add to, reorder, and/or modify any of the acts shown. The operations of the method may be implemented by a processing system, or its components as described herein. For example, the operations of method 200 may be performed by a processing system as described with reference to FIG. 10. Alternatively, a computer-readable medium may include instructions that, when executed by a processing system with a processor, cause the processing system to perform the acts of FIG. 2.

Method 200 may be performed a single time, or multiple times. It may be performed on an as-desired basis, or on a reoccurring schedule. For example, the method 200 may be performed monthly, weekly, daily, hourly, once per minute, once per second, etc., or at any other interval. In at least one embodiment, method 200 is performed daily.

Method 200 integrates a feature importance algorithm of a set of time-series data and probabilistic forecasting using Monte Carlo simulations. This two-layered approach addresses both interpretability and uncertainty quantification, enabling robust and risk-aware decision-making for resource production projects.

As an overview of method 200, a set of time-series data associated with a resource production is obtained that includes data associated with a set of features. The set of time-series data is used to determine the amount of change in the resource production from one time period to the next. In some embodiments, a regime is determined for each time period based on the corresponding amount of change. A feature importance analysis (e.g., SHAP) is applied to the set of time-series data using one or more models to determine a relative importance of each feature over time to a resource production forecast. Monte Carlo simulations are applied to one or more models using data associated with a subset of the set of features that are selected based on the relative importances determined for the features. Applying the Monte Carlo simulations yield an oil production estimate and an uncertainty range. An uncertainty is determined based on the uncertainty range and on values of the selected features that were determined using the feature importance analysis.

At act 210, a set of time-series data 212 associated with production of a resource is obtained. The set of time-series data 212 may include data for a plurality of time periods that together cover a total amount of time. For example, the set of time-series data 212 may include hourly data covering a 24-hour day. This may be desired, for example, if the method 200 is being performed on a daily basis, using raw well performance data. The data includes a set of features (e.g., average downhole pressure, average choke size, average downhole temperature, average annulus pressure, average wellhead pressure, etc.) associated with the production of the resource over the plurality of time periods. The set of time-series data 212 includes, for each time period, a resource production value and values of the features for the time period. The time-series dataset may be represented as:

x={{x_{t,i}}|t∈{1,2, . . . ,T},i∈{1,2, . . . ,n}}

where x_{t,i} is the value of the i-th feature at time t, T is the total number of time periods, and n is the number of features.

The data may be received from sensors associated with the resource, from one or more databases, or a combination of both. In some embodiments, the time-series data includes raw well performance time-series data. In some embodiments, the amount of data is based on the interval at which the method is performed. For example, if method 200 is performed on a monthly, daily, or hourly basis, the time periods may respectively correspond to weekly, hourly, or per minute. In some embodiments, the resource is a liquid, such as a petroleum resource. In some embodiments, the resource is a gas, such as natural gas or helium. In some embodiments, the production is associated with resources for storage, such as carbon dioxide for carbon sequestration. The production may be associated with other types of resources as well, as discussed herein.

At act 214, the amount of change of the production value of the time-series data from one time period to the next. is determined. For example, the amount of change associated with a time period tᵢ may be an amount or percentage of the change of the resource production from the adjacent previous time period tᵢ₋₁.

At optional act 215, one of a set of regimes is determined for each time period, based on the amount of change associated with the time period. Each time period is associated with its own regime 217. In one example, the regime 217 associated with a time period may be a first value (e.g., a “spike” regime) when production from the previous time period rises more than a first threshold (e.g., a first percentage), a second value (e.g., a “dip” regime) when production from the previous time period falls more than a second threshold (e.g., a second percentage), and a third value (e.g., a “steady” regime) for everything else. In one example, the first percentage may be 20% and the second percentage may be −20%. Other thresholds and percentages may also be used. Other types of regimes 217 may alternatively be used. Further, although three regime values are used in the present example, more or less than three values may alternatively be used.

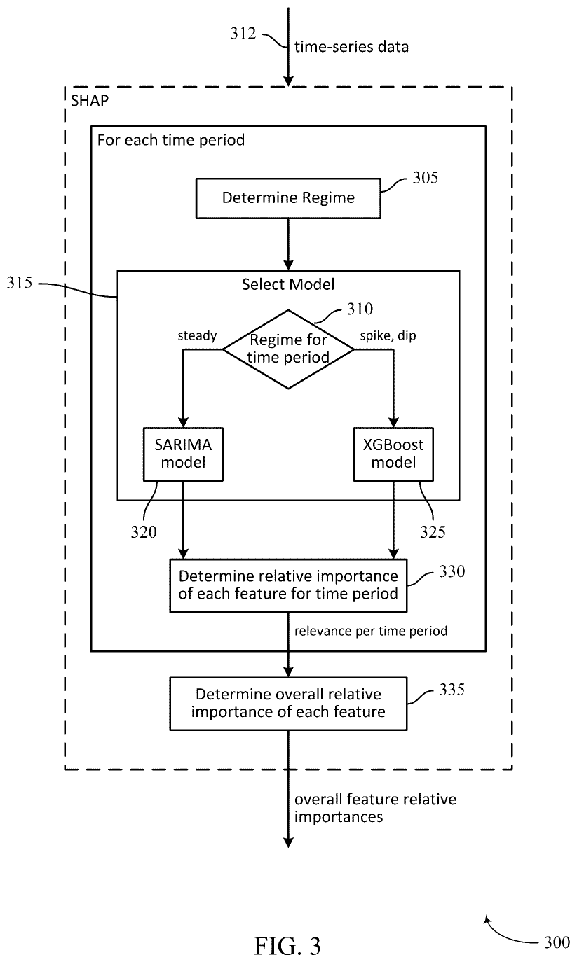

At act 220, a feature importance algorithm is applied to the set of time-series data 212 to determine an overall relative importance of each feature to the resource production forecast over time. The feature importance algorithm uses one or more models to apply to the data to determine the relative importances. In at least one embodiment, the feature importance algorithm is a SHAP algorithm. In at least one embodiment, a relative importance of each feature to the forecast is determined for each time period, using the model. An overall relative importance of each feature over time is determined based on the relative importances of each feature determined for each time period. See FIG. 3 for more details about applying a feature importance algorithm, according to one example.

In at least one embodiment, one of a set of models is determined for applying to the data associated with the time period, based on the amount of change of the production value determined at act 214. In at least one embodiment, the model that is used for the time period is based on the regime 217 associated with the time period, determined at act 215. See FIG. 3 for more details associated with determining the overall relative importance of each feature, according to one example.

At act 225, a subset of the features of the time-series data 212 is selected based on the overall relative importances of the features to the production value over time, determined at act 220. For example, the subset may include the features determined to have the highest relative importances in act 220. In some embodiments, the subset includes only those features determined to have a relative importance that satisfies a predefined importance threshold. For example, features having a relative importance of 60% or higher may be included in the subset. Other relative importance percentages may alternatively be used, such 70% or higher, 75% or higher, 80% or higher, etc. In some embodiments, the subset of features may include only a predefined quantity of features, such as 3, 4, 5, 6, 7, or 8. Other quantities may also be possible. In some embodiments, the quantity of features in the subset of features are based on a total number of features in the time-series data. In some embodiments, the subset of features is selected automatically. In other embodiments, the subset of features may be selected by hand or a combination of both automatically and by hand.

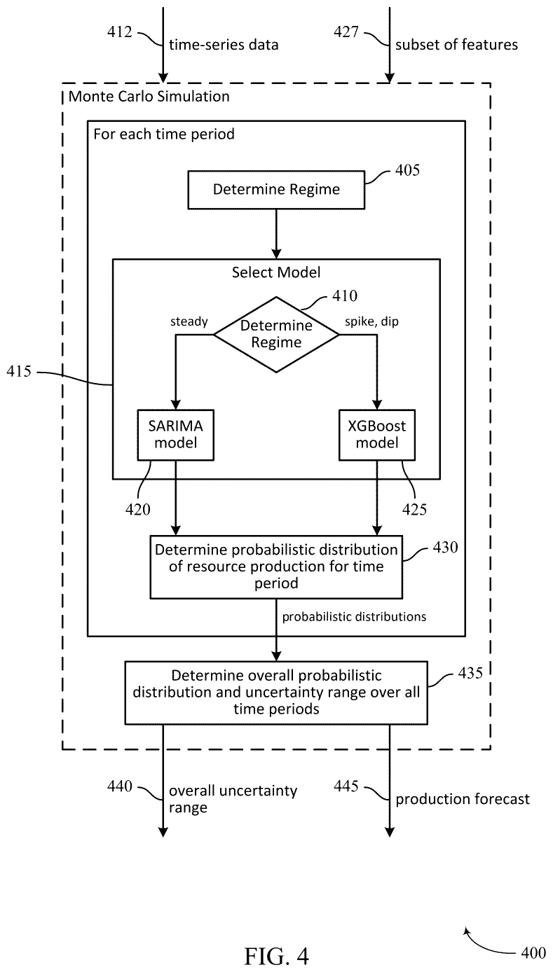

At act 230, Monte Carlo simulations are applied to the set of time-series data to determine a resource production forecast and an uncertainty range. For each time period, a model is determined for applying to the data associated with the time period, based on the amount of change of the resource production value determined at act 214. In at least one embodiment, the model that is used is based on the regime 217 associated with the time period, determined at act 215. See FIG. 4 for more details associated with determining a model for applying the Monte Carlo simulation, according to one example.

For each time period, a Monte Carlo simulation is performed using the determined model and the subset of features selected at act 225. In the simulations, random values are used for the features to obtain random outputs associated with the time period. This yields a probabilistic distribution of resource production forecasts for the time period. The simulations also yield an uncertainty range associated with the time period. An overall probabilistic distribution of resource production forecasts, an overall resource production forecast, and an overall uncertainty range is determined based on the probabilistic distributions and uncertainty ranges determined for each time period.

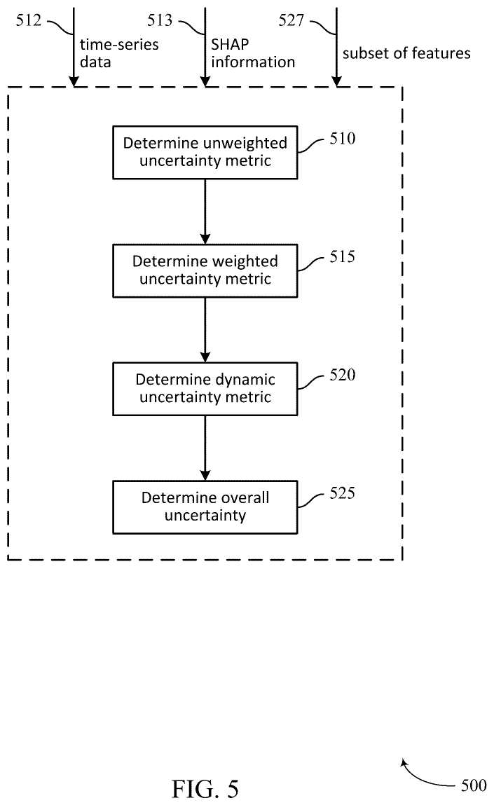

At act 235, an uncertainty associated with the overall resource production forecast is determined, based on the overall uncertainty range determined at act 230 and information determined by applying the feature importance algorithm at act 220. In some embodiments, the overall uncertainty is based on multiple approaches to uncertainty quantification that leverage one or more of feature-specific contributions, interdependencies among features, dynamic feature behavior, and/or probabilistic modelling. This may provide a robust and interpretable approach with accurate quantification of associated uncertainties that may be due to well related attributes, gas production, and water volume. Incorporating additional features into the uncertainty calculation may improve the robustness and accuracy of the forecast by capturing underlying relationships between these features and the target (oil production). See FIG. 5 for more details associated with determining an uncertainty, according to one example.

FIG. 3 is a block diagram 300 illustrating how a feature importance algorithm is applied to a set of time-series data 312, according to at least one embodiment. In at least one embodiment, the block diagram 300 may correspond to act 220 of method 200. In that case, the time-series data 312 may correspond to the time-series data 212.

Acts 305, 315, and 330 are repeated for each time period associated with the time-series data 312.

At act 305 a regime for the time period is determined. The regime is one of a set of regimes and is based on the amount of change of the production from the immediately previous time period, as discussed with respect to method 200. In the depicted embodiment, the set of regimes include a spike regime, which corresponds to time periods in which production has risen more than a first threshold from the prior time period, a dip regime, which corresponds to time periods in which production has fallen more than a second threshold from the prior time period and a steady regime, which corresponds to the rest of the time periods. Other regimes are also possible. In one example, the first percentage may be 20% and the second percentage may be −20%. Other percentages may also be used. Other types of regimes may alternatively be used. Further, although three regime values are used in the present example, more or less than three values may alternatively be used. The regimes for the time periods may be determined individually, as shown, or at the same time. In at least one embodiment, the regimes may be obtained from an external act (such as act 215 of method 200). In those embodiments, act 305 may be omitted.

At act 315, one of a set of trained models is automatically selected for applying to the data associated with the time period. The trained model is automatically selected from the other trained models in the set based on the regime associated with the time period. Any type of trained model may be included in the set of trained models. For example, the set may include, but is not limited to, ARIMA, ARMA, and VAR models, as well as recurrent neural networks, transformers and exponential smoothing methods. In some examples, a same model may be selected for two or more of the regimes. In at least one embodiment, only two models are used with one of the models being selected for two of the three regimes.

In the depicted embodiment, as shown at 310, a SARIMA model 320 is automatically selected if a steady regime is associated with the time period and an XGBoost model 325 is automatically selected if a spike regime or dip regime is associated with the time period. An XGBoost model may handle more scattered data better than a SARIMA model.

A SARIMA model is a versatile and widely used time series forecasting model. It is a statistical analysis model that uses time-series data to predict future trends. The SARIMA model is a form of regression analysis that gauges the strength of one dependent variable relative to other changing variables. The model's goal is to predict future value moves by examining the differences between values in the series instead of through actual values. A SARIMA model includes a seasonality (S) component, an autoregressive (AR) component, a moving average (MA) component, and an integration (I) component. A statistical model is autoregressive if it predicts future values based on past values. The AR portion of the model makes predictions based on previously observed values, which can be expressed as AR(p) where p specifies the number of previous data points to look at. As stated below, where X represents observations from previous time points and φ represents φ the weights.

AR(Xᵢ,p)=φ₁Xₜ₋₁+φ₂Xₜ₋₂+φ₃Xₜ₋₃+ . . . +φₚXₜ₋ₚ

For example, if p=3, then the current time point is dependent on the values from the previous three time points.

The MA portion of the model, MR(q) adjusts the model based on the average prediction errors from the previous q observations, which can be stated as below, where e represents the error terms and θ represents the weights. The q value determines the number of error terms to include in the moving average window.

MR(Xₜ,q)=eₜ+θ₁eₜ₋₁+θ₂eₜ₋₂+ . . . +θ_{q}e_{t-q}

The I portion builds upon the AR portion and the MA portion by introducing degree of differencing components (specified as the parameter d) —ARIMA (p, d, q). This is to address when an obvious trend has been observed in the time-series data.

Finally, the S portion builds on the ARIMA portions to allow data with seasonal patterns to be handled. The seasonal patterns are repeating cycles in the time series. The patterns may be repeated in any regular interval, short or long. To remove the seasonal component of the time series, seasonal differencing is applied, which is the process of subtracting the time-series data by a lag that equals the seasonality. This allows for more straightforward modeling.

SARIMA models attempt to filter out high-frequency noise and repeating cycles in the data to detect local trends based on linear dependence in observations in the series. SARIMA models have two distinct advantages over other types of models: first, they can be easily interpreted in retrospective studies; and second, model selection can be performed over a time series in an automated fashion to maximize prediction accuracy. SARIMA models suffer from two drawbacks: first, they assume linear relationships between independent and dependent variables; and second, they assume a constant standard deviation in errors over time.

XGBoost is an advanced machine learning algorithm designed for efficiency, speed, and high performance. Traditional machine learning models like decision trees and random forests are easy to interpret but often struggle with accuracy on complex datasets. XGBoost is a type of ensemble learning method. Ensemble learning combines multiple weak models to form a stronger model. Conventional decision trees are frequently developed by expanding each branch until a stopping condition is satisfied, or in a depth-first fashion. On the other hand, XGBoost builds trees level-wise or breadth-first. It adds nodes for every feature at a certain depth before moving on to the next level, so the tree can be grown one level at a time. XGBoost uses decision trees as its base learners combining them sequentially to improve the model's performance. Each new tree is trained to correct the errors made by the previous tree and this process is called boosting. Mathematically, the model can be represented as:

$${y}_{i} = {\sum }_{k = 1}^{K} {f}_{k} ( {x}_{i} )$$

where yᵢ is the final predicted value for the i^{th} data point, K is the number of trees in the ensemble, and fₖ(xᵢ) represents the prediction of the K^{th} tree for the i^{th} data point.

An objective function in XGBoost consists of two parts: a loss function and a regularization term. The loss function measures how well the model fits the data and the regularization term simplifies complex trees. The XGBoost model can be optimized iteratively by adding new trees at each step to improve the model. By calculating the information gain for every possible split at each node, XGBoost selects the split that results in the largest gain, which effectively reduces the errors and improves the model's performance.

At act 330, the relative importance of the features is determined for the time period using the model selected at 315. A feature importance algorithm is applied to the data associated with the time period to determine the relative importance of each feature for the time period. For example, the relative importance of each feature may be determined by applying the feature importance algorithm to the data based on a forecast produced by the SARIMA model 320 or the XGBoost model 325. The feature importance algorithm may generate a list of features along with a respective score that represents a relative importance of the feature to the model for the time period. In some examples, the relative importance of each feature may be reflected by a percentage value. In at least one embodiment, the feature importance algorithm is a SHAP algorithm.

Acts 305, 315, and 330 are performed for each time period until they have been performed for all time periods associated with the time-series data.

At act 335, an overall relative importance of each feature over time is determined based on the relative importances of the features determined for each time period. In some embodiments, the overall relative importance may be determined by aggregating and/or averaging the relative importances associated with the time periods. Along with the overall relative importance, other information associated with each feature may also be determined, such as variances, standard deviations, etc. In at least one embodiment, the overall relative importance of each feature, collectively known as the overall feature relative importances, correspond to the overall feature relative importances of that are used to select the subset of features at act 225 of method 200.

FIG. 4 is a block diagram 400 illustrating how a Monte Carlo simulation is applied to a set of time-series data 412 associated with a subset of its features 427, according to at least one embodiment. In at least one embodiment, the block diagram 400 may correspond to act 230 of method 200. In that case, the time-series data 412 may correspond to the time-series data 212 and the subset of features 427 may correspond to the subset of features selected at act 225.

Acts 410, 415 and 430 are repeated for each time period associated with the time-series data 412.

At act 405 a regime for the time period is determined. The regime is one of a set of regimes and is based on the amount of change of the production from the immediately previous time period, as discussed with respect to method 200. In the depicted embodiment, the set of regimes include a spike regime, which corresponds to time periods in which production has risen more than a first threshold from the prior time period, a dip regime, which corresponds to time periods in which production has fallen more than a second threshold from the prior time period and a steady regime, which corresponds to the rest of the time periods. Other regimes are also possible. In one example, the first percentage may be 20% and the second percentage may be −20%. Other percentages may also be used. Other types of regimes may alternatively be used. Further, although three regime values are used in the present example, more or less than three values may alternatively be used. The regimes for the time periods may be determined individually, as shown, or at the same time. In at least one embodiment, the regimes may be obtained from an external act (such as act 215 of method 200). In those embodiments, act 405 may be omitted.

At act 415, one of a set of trained models is automatically selected for applying to the data associated with the time period. The trained model is automatically selected from the other trained models in the set based on the regime associated with the time period. Any type of trained model may be included in the set of trained models. For example, the set may include, but is not limited to, ARIMA, ARMA, and VAR models, as well as recurrent neural networks, transformers and exponential smoothing methods. In some examples, a same model may be selected for two or more of the regimes. In at least one embodiment, only two models are used with one of the models being selected for two of the three regimes. In the depicted embodiment, as shown at 410, a SARIMA model 420 is automatically selected if a steady regime is associated with the time period and an XGBoost model 425 is automatically selected if a spike regime or dip regime is associated with the time period.

At act 430, a probabilistic distribution of resource production for the time period is determined by applying a Monte Carlo simulation to the data using the model selected at 415. To do so, a plurality of simulations is conducted for the time period, applying the trained model to the subset of features. For example, the simulations for the time period may be applied using the SARIMA model 420 or the XGBoost model 425. In the simulations, random values are used for the subset of features to obtain random outputs associated with the time period to generate a probabilistic distribution of the production forecast associated with the time period. In some embodiments, the range of random values may be based on information determined during the application of the feature importance algorithm (e.g., SHAP) to the time-series data, discussed earlier. For example, the range of values used for each feature i at each time period t may be modeled as a normal distribution:

$${x}_{t , i} ∼ N ( {μ}_{i} , {σ}_{i}^{2} )$$

Where Nis the number of simulations, μᵢ is the mean SHAP value of feature i, and σᵢ is the standard deviation of feature i derived from SHAP variance.

For each simulation k of the time period, feature samples

$${x}_{t , i}^{( k )}$$

are drawn from their respective distributions. These samples are input into the trained models (e.g., XGBoost model 425 for spike and dip regimes, SARIMA model 420 for steady regimes) to generate simulated production values

$${y}_{c}^{( k )} : {y}_{t}^{( k )} = Model ( {x}_{t , 1}^{( k )} , {x}_{t , 2}^{( k )} , … , {x}_{t , n}^{( k )} )$$

The resulting N simulations form a probabilistic distribution of yₜ, capturing the range of possible outcomes and their associated probabilities for the time period. The combination of random outputs comprise the probabilistic distribution of the production forecast associated with the time period.

The output distribution of yₜ is summarized to extract various probabilistic metrics for the time period. For example, a mean and standard deviation may be determined for the time period. Further, probabilistic thresholds representing optimistic, median, and pessimistic scenarios (P₁₀, P₅₀, and P₉₀, respectively) may be determined, based, for example, on the standard deviation. An uncertainty range (also known as a confidence interval) for the time period may also be determined. In some examples, the uncertainty range may be the difference between the optimistic and pessimistic scenario thresholds (e.g., P₉₀-P₁₀).

Acts 405, 415, and 430 are performed for each time period until they have been performed for all time periods associated with the time-series data.

At act 435, an overall probabilistic distribution and overall uncertainty range 440 of the production forecast over time is determined based on the probabilistic distributions and uncertainty ranges associated with the time periods. In some embodiments, the overall probabilistic distribution and/or the overall uncertainty range may be determined by aggregating and/or averaging the probabilistic distributions determined for the time periods. A production forecast 445 may be determined based on the overall probabilistic distribution. In at least one embodiment, the overall uncertainty range 440 and the production forecast 445 correspond respectively to the uncertainty range and resource production forecast of method 200.

FIG. 5 is a block diagram depicting a series of acts in a computer-implemented method 500 for determining an overall uncertainty associated with a resource production forecast, according to at least one embodiment. To define an accurate and representative version of the uncertainty calculation, an uncertainty metric may be based on other features in the data. Incorporating additional features into the uncertainty metric can improve the robustness and accuracy of the forecast by capturing the underlying relationships between these features and the target (e.g. oil production). This may be based on multiple approaches to uncertainty quantification by leveraging feature-specific contributions, interdependencies among features, dynamic feature behavior and probabilistic modelling—thus providing a robust and interpretable approach with accurate quantification of associated uncertainties that may be due to well related attributes, gas production and/or water volume. The overall uncertainty may be based on information from time-series data 512 based on a subset of features 527 in the data and/or information 513 determined from a feature relative importance determination (e.g., SHAP). The method 500 may correspond to act 235 of method 200. In that case, the time-series data 512 may correspond to the time-series data 212, the subset of features 527 may correspond to the subset of features selected at act 225, and the feature relative importance determination may correspond to information obtained at act 220.

In the depicted embodiment, the overall uncertainty is based on various metrics that are based on other features in the data. For example, an uncertainty metric may be based on information associated with features of the time-series data. In some embodiments, an uncertainty metric may be based on information associated with the features selected for the Monte Carlo simulation. In some embodiments, an uncertainty metric may be based on information determined by the feature importance algorithm (e.g., SHAP) application to the data. For example, one or more uncertainty metrics may be based on a covariance matrix of SHAP values across features. Feature interactions and interdependencies can amplify or reduce the overall uncertainty, and the covariance matrix of SHAP values may be incorporated to account for these correlations.

At act 510, an aggregated uncertainty metric is determined. In some embodiments, to determine the aggregated uncertainty metric U₁, an overall uncertainty contribution from all the features is computed:

$${U}_{1} = \sqrt{{\sum }_{i = 1}^{n} {σ}_{{ϕ}_{i}}^{2}}$$

where n is the number of features.

At act 515, a correlation-aware uncertainty metric is determined which accounts for feature correlations. In some embodiments, a weight vector w is determined for each feature i that represents the relative importance of the feature, based on its mean SHAP value.

$${w}_{i} = \frac{{\overline{ϕ}}_{i}}{{\sum }_{j = 1}^{n} {\overline{ϕ}}_{j}}$$

In some embodiments, the correlation-aware uncertainty metric U₂, which accounts for feature correlations, is determined that incorporates the weights for each feature:

U₂=\sqrt{W^{T}Σ^{W}}

where w is the weight vector and Σ is the covariance matrix of SHAP values

At act 520, a dynamic uncertainty metric is determined. For time-series data, feature contributions to uncertainty may vary across time, reflecting changing operational conditions. A dynamic uncertainty metric is defined to capture these temporal variations. In some embodiments, a time-dependent SHAP variance is computed by computing the variance of SHAP values for each feature i at each time t:

$${σ}_{{ϕ}_{t , 1}}^{2} = VAR ( {ϕ}_{t , i} \vert t )$$

In some embodiments, the dynamic uncertainty metric U₃ is determined for each time period by incorporating the SHAP variances associated with the time period:

$${U}_{3} ( t ) = \sqrt{{\sum }_{i = 1}^{n} {σ}_{{ϕ}_{t , i}}^{2}}$$

At act 525, a final uncertainty metric is determined by combining the contributions from the aggregated uncertainty metric, correlation-aware uncertainty metric, and the dynamic metric:

U_{final}=∝₁U₁+∝₂U₂+∝₃U₃

where ∝₁, ∝₂, and ∝₃ are weights reflecting the relative importance of each component, which may be calibrated based on domain expertise or data-driven methods. The final uncertainty metric may be used to determine an accurate and representative version of the uncertainty calculation.

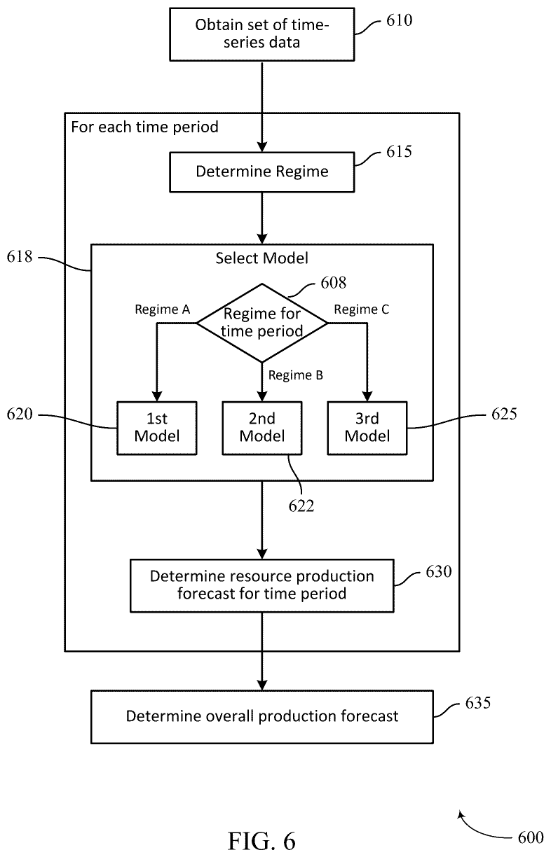

FIG. 6 is a block diagram illustrating a method of forecasting resource production using time-series data, according to at least one embodiment. Using method 600, a resource production forecast, such as an oil or a gas production forecast, may be determined. Although method 600 is presented as applying to oil production forecasts, it can also apply to other types of resource production forecasting, as discussed herein.

Alternative implementations may omit, add to, reorder, and/or modify any of the acts shown. The operations of the method may be implemented by a processing system, or its components as described herein. For example, the operations of method 600 may be performed by a processing system as described with reference to FIG. 10. Alternatively, a computer-readable medium may include instructions that, when executed by a processing system with a processor, cause the processing system to perform the acts of FIG. 6. Similar to the other methods discussed herein, method 600 may be performed a single time, or multiple times, on an as-desired basis, or on a reoccurring schedule.

At act 610, a set of time-series data associated with production of a resource is obtained. This may be similar to act 210 discussed with respect to method 200.

Acts 615, 618, and 630 are repeated for each time period associated with the time-series data 612.

At act 615, a regime for the time period is determined. The regime is one of a set of regimes and is based on the amount of change of the production from the immediately previous time period. For example, a regime associated with a time period tᵢ may be based on a percentage of the change of the resource production from the adjacent previous time period tᵢ₋₁. In one example, the regimes may include a regime A, corresponding to a spike regime when production from the previous time period rises more than a first threshold (e.g., a first percentage), a regime B, corresponding to a dip regime when production from the previous time period falls more than a second threshold (e.g., second percentage), and a regime C, corresponding to a steady regime for everything else. In one example, the first percentage may be 20% and the second percentage may be −20%. Other percentages may also be used. Other types of regimes may alternatively be used. Further, although three regime values are used in the present example, more or less than three values may alternatively be used. The regimes for the time periods may be determined individually, as shown, or at the same time.

At act 618, one of a set of trained models is automatically selected for applying to the data associated with the time period. The trained model is selected from the other trained models in the set based on the regime associated with the time period. For example, as shown at 608, a first model 620, a second model 622, or a third model 625 may be selected if the regime for the time period is A, B, or C, respectively.

Any type of trained model may be included in the set of trained models. For example, the set may include ARIMA, ARMA, VAR and random forest regression models, as well as recurrent neural networks, transformers and exponential smoothing methods. In at least one embodiment, the first, second, and third models correspond to a SARIMA model, a random forest regression model, and an XGBoost model. In some examples, a same model may be selected for two or more of the regimes. In at least one embodiment, only two models are used with one of the models being selected for two of the three regimes. For example, a SARIMA model may be selected for a steady regime, and an XGBoost model may be selected for a spike regime and a dip regime, similar to other embodiments discussed herein.

At act 630, a resource production forecast is determined for the time period using the model selected at act 618. In at least one embodiment, the model is applied using all of the features associated with the data. In at least one embodiment, the model is applied using a subset of the features. In at least one embodiment, the resource production forecast is determined by simply applying the particular model to the data. In other embodiments, an additional application is applied to the data to obtain the resource production forecast or a probabilistic distribution. For example, a Monte Carlo simulation may be applied to the model, as discussed with respect to block diagram 400.

Acts 615, 618, and 630 are repeated for each time period until they have been performed for all the time periods associated with the time-series data.

At act 635, an overall resource production forecast over time is determined based on the resource production forecasts associated with the time periods. In some embodiments, the overall production forecast may be determined by aggregating and/or averaging the resource production forecasts associated with the time periods. In some embodiments, a separate production forecast may be determined for each regime. That is, a first overall production forecast may be determined based on the individual resource production forecasts associated with a first regime, a second overall production forecast may be determined based on the individual resource production forecasts associated with a second regime, and so forth. If a Monte Carlo simulation is used at act 630, an overall probabilistic distribution and overall uncertainty range of the production forecast over time may be determined based on probabilistic distributions and uncertainty ranges associated with each time period, and a resource production forecast may be determined based on the overall probabilistic distribution, similar to act 435.

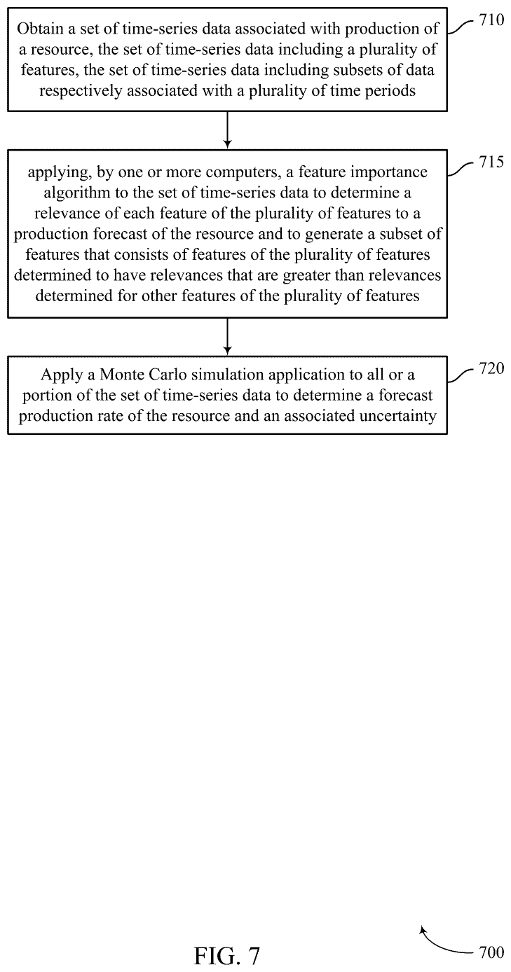

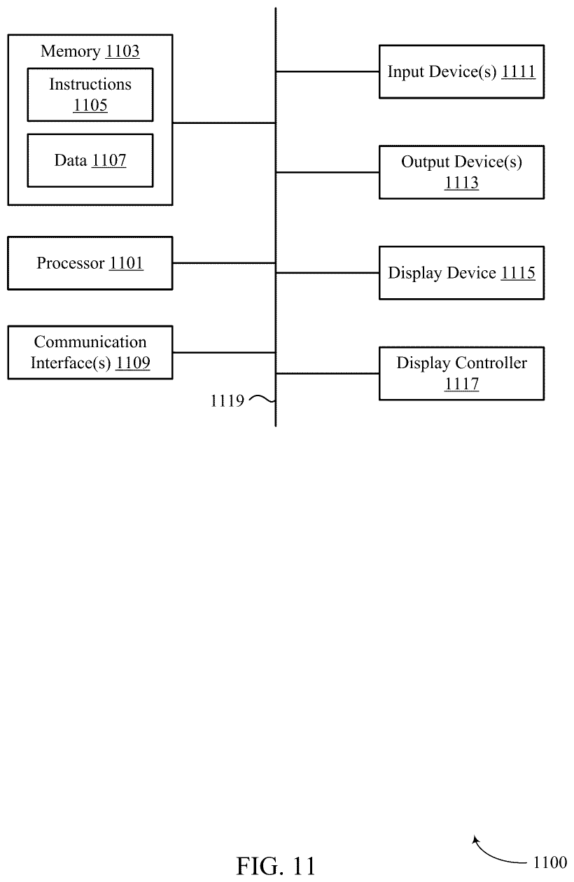

FIG. 7 depicts a series of acts in a computer-implemented method 700 for determining a production rate forecast of a resource according to at least one embodiment. The method may be for protecting resources associated with petroleum-industry operations. Alternative implementations may omit, add to, reorder, and/or modify any of the acts shown. The operations of method 700 may be implemented by a processing system or its components as described herein. For example, the operations of method 700 may be performed by a processing system as described with reference to FIG. 11. Alternatively, a computer-readable medium may include instructions that, when executed by a processing system with a processor, cause the processing system to perform the acts of FIG. 7

At act 710, the method may include obtaining a set of time-series data associated with production of a resource, the set of time-series data including a plurality of features, the set of time-series data including subsets of data respectively associated with a plurality of time periods. The operations of act 710 may be performed in accordance with examples as disclosed herein.

At act 715, the method may include applying, by one or more computers, a feature importance algorithm to the set of time-series data to determine a relevance of each feature of the plurality of features to a production forecast of the resource and to generate a subset of features that consists of features of the plurality of features determined to have relevances that are greater than relevances determined for other features of the plurality of features. The operations of act 715 may be performed in accordance with examples as disclosed herein.

At act 720, the method may include applying, by the one or more computers, a Monte Carlo simulation to a portion of the set of time-series data associated with the subset of features to determine a production rate forecast of the resource and an associated uncertainty. The operations of act 720 may be performed in accordance with examples as disclosed herein.

In some examples, an apparatus as described herein may perform a method such as the method 700. The apparatus may include, features, circuitry, logic, means, or instructions (e.g., a non-transitory computer-readable medium storing instructions executable by a processor) for obtaining a set of time-series data associated with production of a resource, the set of time-series data including a plurality of features, the set of time-series data including subsets of data respectively associated with a plurality of time periods; applying, by one or more computers, a feature importance algorithm to the set of time-series data to determine a relevance of each feature of the plurality of features to a production forecast of the resource and to generate a subset of features that consists of features of the plurality of features determined to have relevances that are greater than relevances determined for other features of the plurality of features; and applying, by the one or more computers, a Monte Carlo simulation to a portion of the set of time-series data associated with the subset of features to determine a production rate forecast of the resource and an associated uncertainty.

In some examples of the method 700 and the apparatus described herein, the feature importance algorithm may be a SHAP algorithm.

In some examples of the method 700 and the apparatus described herein, applying the Monte Carlo simulation may include applying, by the one or more computers for each time period of the plurality of time periods, a Monte Carlo simulation to a portion of the subset of data respectively associated with the time period.

In some examples of the method 700 and the apparatus described herein, the uncertainty may be based on information determined from applying the feature importance algorithm to the set of time-series data.

Some examples of the method 700 and the apparatus described herein may further include operations, features, circuitry, logic, means, or instructions for performing an action based on the production rate forecast and the uncertainty.

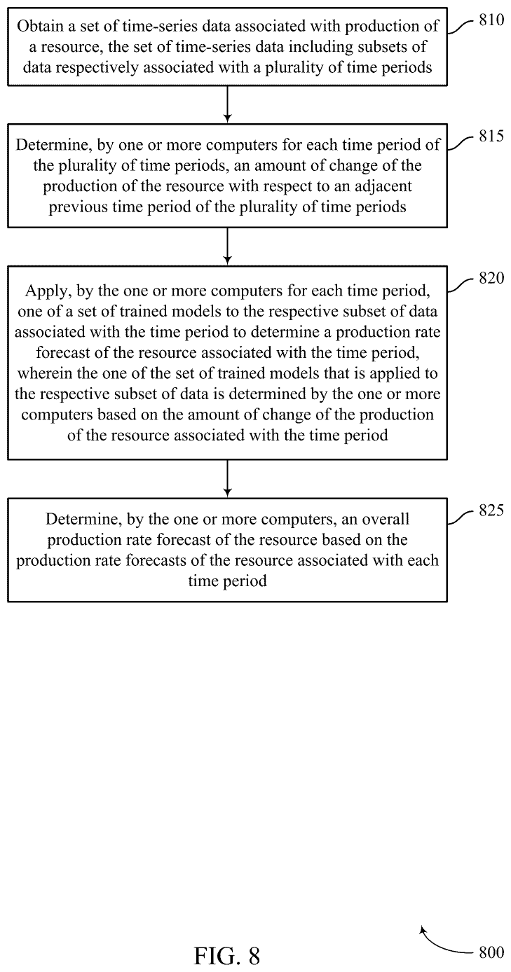

FIG. 8 depicts a series of acts in a computer-implemented method 800 for determining a production rate forecast of a resource according to at least one embodiment. The method may be for protecting resources associated with petroleum-industry operations. Alternative implementations may omit, add to, reorder, and/or modify any of the acts shown. The operations of method 800 may be implemented by a processing system or its components as described herein. For example, the operations of method 800 may be performed by a processing system as described with reference to FIG. 11. Alternatively, a computer-readable medium may include instructions that, when executed by a processing system with a processor, cause the processing system to perform the acts of FIG. 8

At act 810, the method may include obtaining a set of time-series data associated with production of a resource, the set of time-series data including subsets of data respectively associated with a plurality of time periods. The operations of act 810 may be performed in accordance with examples as disclosed herein.

At act 815, the method may include determining, by one or more computers for each time period of the plurality of time periods, an amount of change of the production of the resource with respect to an adjacent previous time period of the plurality of time periods. The operations of act 815 may be performed in accordance with examples as disclosed herein.

At act 820, the method may include applying, by the one or more computers for each time period, one of a set of trained models to the respective subset of data associated with the time period to determine a production rate forecast of the resource associated with the time period, wherein the one of the set of trained models that is applied to the respective subset of data is determined by the one or more computers based on the amount of change of the production of the resource associated with the time period. The operations of act 820 may be performed in accordance with examples as disclosed herein.

At act 825, the method may include determining, by the one or more computers, an overall production rate forecast of the resource based on the production rate forecasts of the resource associated with each time period. The operations of act 825 may be performed in accordance with examples as disclosed herein.

In some examples, an apparatus as described herein may perform a method such as the method 700. The apparatus may include, features, circuitry, logic, means, or instructions (e.g., a non-transitory computer-readable medium storing instructions executable by a processor) for obtaining a set of time-series data associated with production of a resource, the set of time-series data including subsets of data respectively associated with a plurality of time periods; determining, by one or more computers for each time period of the plurality of time periods, an amount of change of the production of the resource with respect to an adjacent previous time period of the plurality of time periods; applying, by the one or more computers for each time period, one of a set of trained models to the respective subset of data associated with the time period to determine a production rate forecast of the resource associated with the time period, wherein the one of the set of trained models that is applied to the respective subset of data is determined by the one or more computers based on the amount of change of the production of the resource associated with the time period; determining, by the one or more computers, an overall production rate forecast of the resource based on the production rate forecasts of the resource associated with each time period.

In some examples of the method 800 and the apparatus described herein, the set of trained models may include a SARIMA model and an XGBoost model.

In some examples of the method 800 and the apparatus described herein, a first model may be applied to the respective subset of data when the amount of change of the production of the resource associated with the time period satisfies a threshold and a second model that is different than the first model may be applied to the respective subset of data when the amount of change fails to satisfy the threshold.

In some examples of the method 800 and the apparatus described herein, determining, for each time period, an amount of change of the production of the resource with respect to an adjacent previous time period may include: determining, for a first time period, a first amount of change of the production of the resource with respect to an adjacent first previous time period; and determining, for a second time period, a second amount of change of the production of the resource with respect to an adjacent second previous time period.

In some examples of the method 800 and the apparatus described herein, applying, for each time period, one of a set of trained models to the respective subset of data associated with the time period includes: applying, for a first time period, a first trained model to the respective subset of data associated with the first time period based on the first amount of change of the production of the resource; and applying, for a second time period, a second trained model that is different than the first model to the respective subset of data associated with the second time period based on the second amount of change of the production of the resource.

Some examples of the method 800 and the apparatus described herein may further include operations, features, circuitry, logic, means, or instructions for determining, for each time period, one of a set of regimes based on the amount of change of the production of the resource associated with the time period, wherein the one of the set of trained models that is applied to the respective subset of data associated with the time period is based on the regime associated with the time period.

In some examples of the method 800 and the apparatus described herein, a first model may be applied to the respective subset of data when the time period is associated with a first regime of the set of regimes and a second model that is different than the first model may be applied to the respective subset of data when the time period is associated with a second regime of the set of regimes.

In some examples of the method 800 and the apparatus described herein, a third model may be applied to the respective subset of data when the time period is associated with a third regime of the set of regimes.

In some examples of the method 800 and the apparatus described herein, the set of regimes may include a first regime associated with time periods in which the amount of change of the production of the resource has risen more than a first threshold, a second regime associated with time periods in which the amount of change of the production of the resource has fallen more than a second threshold, and a third regime associated with time periods in which the amount of change of the production of the resource has not raised more than the first threshold nor fallen more than the second threshold.

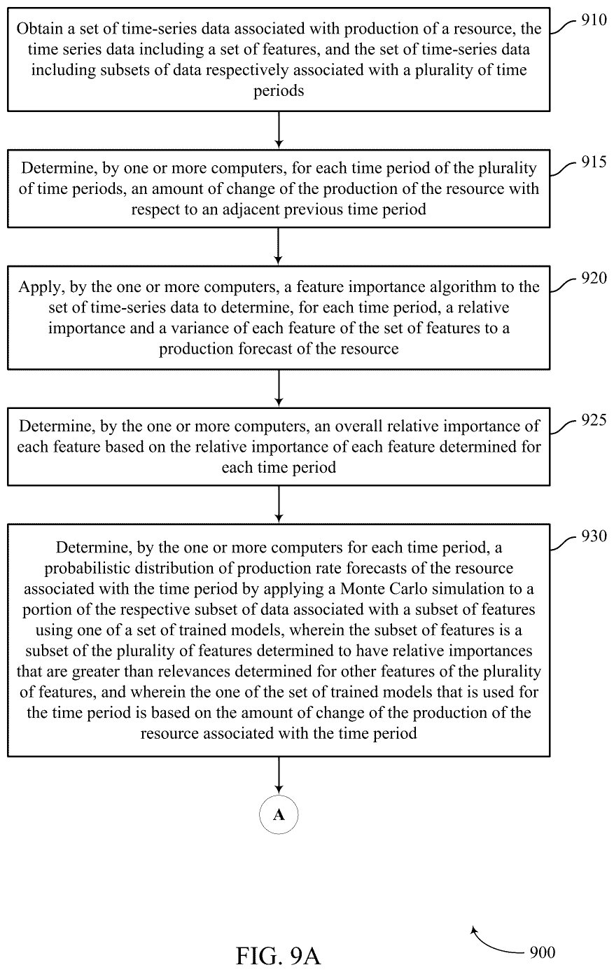

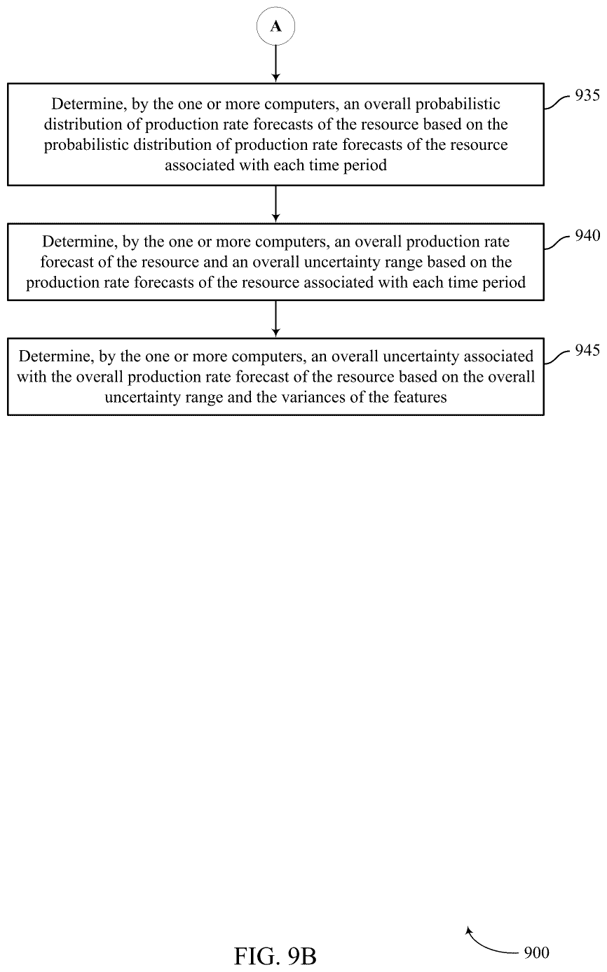

FIGS. 9A and 9B depict a series of acts in a computer-implemented method 900 for determining a production rate forecast of a resource according to at least one embodiment. The method may be for protecting resources associated with petroleum-industry operations. Alternative implementations may omit, add to, reorder, and/or modify any of the acts shown. The operations of method 900 may be implemented by a processing system or its components as described herein. For example, the operations of method 900 may be performed by a processing system as described with reference to FIG. 11. Alternatively, a computer-readable medium may include instructions that, when executed by a processing system with a processor, cause the processing system to perform the acts of FIGS. 9A and 9B

At act 910, the method may include obtaining a set of time-series data associated with production of a resource, the time-series data including a set of features, and the set of time-series data including subsets of data respectively associated with a plurality of time periods. The operations of act 910 may be performed in accordance with examples as disclosed herein.

At act 915, the method may include determining, by one or more computers, for each time period of the plurality of time periods, an amount of change of the production of the resource with respect to an adjacent previous time period. The operations of act 915 may be performed in accordance with examples as disclosed herein.

At act 920, the method may include applying, by the one or more computers, a feature importance algorithm to the set of time-series data to determine, for each time period, a relative importance and a variance of each feature of the set of features to a production forecast of the resource. The operations of act 920 may be performed in accordance with examples as disclosed herein.

At act 925, the method may include determining, by the one or more computers, an overall relative importance of each feature based on the relative importance of each feature determined for each time period. The operations of act 925 may be performed in accordance with examples as disclosed herein.

At act 930, the method may include determining, by the one or more computers for each time period, a probabilistic distribution of production rate forecasts of the resource associated with the time period by applying a Monte Carlo simulation to a portion of the respective subset of data associated with a subset of features using one of a set of trained models, wherein the subset of features is a subset of the plurality of features determined to have relative importances that are greater than relevances determined for other features of the plurality of features, and wherein the one of the set of trained models that is used for the time period is based on the amount of change of the production of the resource associated with the time period. The operations of act 930 may be performed in accordance with examples as disclosed herein.

At act 935, the method may include determining, by the one or more computers, an overall probabilistic distribution of production rate forecasts of the resource based on the probabilistic distribution of production rate forecasts of the resource associated with each time period. The operations of act 935 may be performed in accordance with examples as disclosed herein.

At act 940, the method may include determining, by the one or more computers, an overall production rate forecast of the resource and an overall uncertainty range based on the production rate forecasts of the resource associated with each time period. The operations of act 940 may be performed in accordance with examples as disclosed herein.

At act 945, the method may include determining, by the one or more computers, an overall uncertainty associated with the overall production rate forecast of the resource based on the overall uncertainty range and the variances of the features. The operations of act 945 may be performed in accordance with examples as disclosed herein.

In some examples, an apparatus as described herein may perform a method such as the method 900. The apparatus may include, features, circuitry, logic, means, or instructions (e.g., a non-transitory computer-readable medium storing instructions executable by a processor) for obtaining a set of time-series data associated with production of a resource, the time-series data including a set of features, and the set of time-series data including subsets of data respectively associated with a plurality of time periods; determining, by one or more computers, for each time period of the plurality of time periods, an amount of change of the production of the resource with respect to an adjacent previous time period; applying, by the one or more computers, a feature importance algorithm to the set of time-series data to determine, for each time period, a relative importance and a variance of each feature of the set of features to a production forecast of the resource; determining, by the one or more computers, an overall relative importance of each feature based on the relative importance of each feature determined for each time period; determining, by the one or more computers for each time period, a probabilistic distribution of production rate forecasts of the resource associated with the time period by applying a Monte Carlo simulation to a portion of the respective subset of data associated with a subset of features using one of a set of trained models, wherein the subset of features is a subset of the plurality of features determined to have relative importances that are greater than relevances determined for other features of the plurality of features, and wherein the one of the set of trained models that is used for the time period is based on the amount of change of the production of the resource associated with the time period; determining, by the one or more computers, an overall probabilistic distribution of production rate forecasts of the resource based on the probabilistic distribution of production rate forecasts of the resource associated with each time period; determining, by the one or more computers, an overall production rate forecast of the resource and an overall uncertainty range based on the production rate forecasts of the resource associated with each time period; determining, by the one or more computers, an overall uncertainty associated with the overall production rate forecast of the resource based on the overall uncertainty range and the variances of the features.

In some examples of the method 900 and the apparatus described herein, the feature importance algorithm may be a Shapley Additive explanations (SHAP) algorithm.

Some examples of the method 900 and the apparatus described herein may further include operations, features, circuitry, logic, means, or instructions for determining, for each time period, one of a set of regimes based on the amount of change of the production of the resource associated with the time period, wherein the trained model used for each time period is based on the regime associated with the time period.

In some examples of the method 900 and the apparatus described herein, the set of regimes may include a first regime associated with time periods in which the amount of change of the production of the resource has risen more than a first threshold, a second regime associated with time periods in which the amount of change of the production of the resource has fallen more than a second threshold, and a third regime associated with time periods in which the amount of change of the production of the resource has not raised more than the first threshold nor fallen more than the second threshold.

In some examples of the method 900 and the apparatus described herein, the trained model used for each time period may be a SARIMA model or an XGBoost model, based on the amount of change of the production of the resource associated with the time period.

In some examples of the method 900 and the apparatus described herein, if the amount of change of the production of the resource satisfies a threshold, the trained model is the XGBoost model and if the amount of change of the production of the resource fails to satisfy the threshold, the trained model is the SARIMA model.

In some examples of the method 900 and the apparatus described herein, applying the feature importance algorithm to the set of time-series data may include applying, for each time period, the one of the set of trained models to the respective subset of data used with the Monte Carlo simulation for the time period.

In some examples of the method 900 and the apparatus described herein, determining the overall uncertainty may include determining, by the one or more computers, an unweighted contribution associated with the subset of features; determining, by the one or more computers, a weighted contribution associated with the subset of features; and determining, by the one or more computers, a dynamic contribution associated with the subset of features using the determined variances.

In some examples of the method 900 and the apparatus described herein, the plurality of time periods may include a plurality of hour time periods associated with a 24-hour day.

Some examples of the method 900 and the apparatus described herein may further include operations, features, circuitry, logic, means, or instructions for performing the method daily.

Some examples of the method 900 and the apparatus described herein may further include operations, features, circuitry, logic, means, or instructions for selecting the features of the plurality of features to include in the subset of features based on the determined overall relative importance of each feature of the plurality of features.

Some examples of the method 900 and the apparatus described herein may further include operations, features, circuitry, logic, means, or instructions for generating a list of the features and associated overall relative importances.

In some examples of the method 900 and the apparatus described herein, the set of time-series data may include raw well performance time-series data.

In some examples of the method 900 and the apparatus described herein, the trained model used for the time period may be based on the amount of change of the production of the resource compared to a threshold.

In some examples of the method 900 and the apparatus described herein, the trained model used for the time period may be a first trained model if the amount of change of the production of the resource satisfies the threshold and the trained model used for the time period may be a second trained model if the amount of change of the production of the resource fails to satisfy the threshold.

In some examples of the method 900 and the apparatus described herein, the set of features may include one or more of: average downhole pressure, average choke size, average downhole temperature, average annulus pressure, or average wellhead pressure.

In some examples of the method 900 and the apparatus described herein, the resource may include carbon dioxide for carbon sequestration.

In some examples of the method 900 and the apparatus described herein, the resource may include a gas.

In some examples of the method 900 and the apparatus described herein, the resource may include a petroleum resource.

In some examples of the method 900 and the apparatus described herein, the set of time-series data may include a first subset of data associated with a first time period of the plurality of time periods and a second subset of data associated with a second time period of the plurality of time periods.

In some examples of the method 900 and the apparatus described herein, determining, for each time period, an amount of change of the production of the resource with respect to an adjacent previous time period may include determining, for the first time period that the amount of change of the resource is greater than a threshold; and determining, for the second time period that the amount of change of the resource is not greater than the threshold.

In some examples of the method 900 and the apparatus described herein, determining, for each time period, a probabilistic distribution of production rate forecasts of the resource associated with the time period by applying a Monte Carlo simulation to a portion of the respective subset of data using one of a set of trained models may include determining a probabilistic distribution of production rate forecasts of the resource associated with the first time period by applying a Monte Carlo simulation to a portion of the respective first subset of data using a first trained model of the set of trained models based on the amount of change of the production of the resource associated with the first time period being greater than the threshold; and determining a probabilistic distribution of production rate forecasts of the resource associated with the second time period by applying a Monte Carlo simulation to a portion of the respective second subset of data using a second trained model of the set of trained models based on the amount of change of the production of the resource associated with the second time period being less than the threshold.

FIG. 10 depicts a series of acts in a computer-implemented method 1000 for determining a production rate forecast of a resource according to at least one embodiment. The method may be for protecting resources associated with petroleum-industry operations. Alternative implementations may omit, add to, reorder, and/or modify any of the acts shown. The operations of method 1000 may be implemented by a processing system or its components as described herein. For example, the operations of method 1000 may be performed by a processing system as described with reference to FIG. 11. Alternatively, a computer-readable medium may include instructions that, when executed by a processing system with a processor, cause the processing system to perform the acts of FIG. 10

At act 1010, the method may include obtaining a set of time-series data associated with production of a resource, the time-series data including, for each time period associated with the set of time-series data, values of features associated with the production of the resource. The operations of act 1010 may be performed in accordance with examples as disclosed herein.

At act 1015, the method may include determining, by one or more computers for each time period, a production rate forecast of the resource and a variance of each feature based on the values of the features associated with the time period. The operations of act 1015 may be performed in accordance with examples as disclosed herein.

At act 1020, the method may include determining, by the one or more computers, an overall production rate forecast of the resource based on the production rate forecasts of the resource associated with each time period. The operations of act 1020 may be performed in accordance with examples as disclosed herein.

At act 1025, the method may include determining, by the one or more computers, an unweighted contribution associated with one or more of the features associated with the set of time-series data. The operations of act 1025 may be performed in accordance with examples as disclosed herein.

At act 1030, the method may include determining, by the one or more computers, a weighted contribution associated with the one or more features. The operations of act 1030 may be performed in accordance with examples as disclosed herein.

At act 1035, the method may include determining, by the one or more computers, a dynamic contribution associated with the one or more features based on the determined variances. The operations of act 1035 may be performed in accordance with examples as disclosed herein.

At act 1040, the method may include determining, by the one or more computers, a dynamic contribution associated with the one or more features based on the determined variances. The operations of act 1040 may be performed in accordance with examples as disclosed herein.

In some examples, an apparatus as described herein may perform a method such as the method 1000. The apparatus may include, features, circuitry, logic, means, or instructions (e.g., a non-transitory computer-readable medium storing instructions executable by a processor) for obtaining a set of time-series data associated with production of a resource, the time-series data including, for each time period associated with the set of time-series data, values of features associated with the production of the resource; determining, by one or more computers for each time period, a production rate forecast of the resource and a variance of each feature based on the values of the features associated with the time period; determining, by the one or more computers, an overall production rate forecast of the resource based on the production rate forecasts of the resource associated with each time period; determining, by the one or more computers, an unweighted contribution associated with one or more of the features associated with the set of time-series data; determining, by the one or more computers, a weighted contribution associated with the one or more features; determining, by the one or more computers, a dynamic contribution associated with the one or more features based on the determined variances; and determining, by the one or more computers, a dynamic contribution associated with the one or more features based on the determined variances.

In some examples of the method 1000 and the apparatus described herein, determining the unweighted contribution associated with the one or more of the features associated with the set of time-series data may include determining the unweighted contribution associated with all of the features associated with the set of time-series data.

Some examples of the method 1000 and the apparatus described herein may further include operations, features, circuitry, logic, means, or instructions for applying a feature importance algorithm to the set of time-series data to determine a relative importance of each feature to the overall production rate forecast of the resource, wherein determining the weighted contribution associated with the one or more features includes determining a weight vector w for each feature of the one or more of the features that represents the relative importance of the feature.

Some examples of the method 1000 and the apparatus described herein may further include operations, features, circuitry, logic, means, or instructions for applying a feature importance algorithm to the set of time-series data to determine a relative importance of each feature to the overall production rate forecast of the resource and variances associated with each feature, wherein the determined variances include the variances associated with each feature.

FIG. 11 illustrates certain components that may be included within a computer system 1100 according to at least one embodiment. The computer system 1100 may be used to implement the various computing devices, components, and systems described herein (e.g., by performing computer-implemented instructions). As used herein, a “computing device” refers to electronic components that perform a set of operations based on a set of programmed instructions. Computing devices include groups of electronic components, client devices, server devices, etc. One or more computer system may be used to implement the various devices, components, and systems described herein.

In various implementations, the computer system 1100 represents one or more client devices, server devices, or other computing devices. For example, the computer system 1100 may refer to various types of network devices capable of accessing data on a network, a cloud computing system, or another system. For instance, a client device may refer to a mobile device such as a mobile telephone, a smartphone, a personal digital assistant (PDA), a tablet, a laptop, or a wearable computing device (e.g., a headset or smartwatch). A client device may also refer to a non-mobile device such as a desktop computer, a server node (e.g., from another cloud computing system), or another non-portable device.

The computer system 1100 includes a processing system including a processor 1101. The processor 1101 may be a general-purpose single- or multi-chip microprocessor (e.g., an Advanced Reduced Instruction Set Computer (RISC) Machine (ARM)), a special-purpose microprocessor (e.g., a digital signal processor (DSP)), a microcontroller, a programmable gate array, etc. The processor 1101 may be referred to as a central processing unit (CPU) and may cause computer-implemented instructions to be performed. Although the processor 1101 shown is just a single processor in the computer system 1100 of FIG. 11, in an alternative configuration, a combination of processors (e.g., an ARM and DSP) may be used.

The computer system 1100 also includes a memory 1103 in electronic communication with the processor 1101. The memory 1103 may be any electronic component capable of storing electronic information. For example, the memory 1103 may be embodied as random-access memory (RAM), read-only memory (ROM), magnetic disk storage media, optical storage media, flash memory devices in RAM, on-board memory included with the processor, erasable programmable read-only memory (EPROM), electrically erasable programmable read-only memory (EEPROM), registers, and so forth, including combinations thereof.

Instructions 1105 and data 1107 may be stored in the memory 1103. The instructions 1105 may be executable by the processor 1101 to implement some or all of the functionality disclosed herein. Executing the instructions 1105 may involve the use of the data 1107 stored in the memory 1103. Any of the various examples of modules and components described herein may be implemented, partially or wholly, as instructions 1105 stored in memory 1103 and executed by the processor 1101. Any of the various examples of data described herein may be among the data 1107 stored in memory 1103 and used during the execution of the instructions 1105 by the processor 1101.

A computer system 1100 may also include one or more communication interface(s) 1109 for communicating with other electronic devices. The one or more communication interface(s) 1109 may be based on wired communication technology, wireless communication technology, or both. Some examples of the one or more communication interface(s) 1109 include a Universal Serial Bus (USB), an Ethernet adapter, a wireless adapter that operates according to an Institute of Electrical and Electronics Engineers (IEEE) 802.11 wireless communication protocol, a Bluetooth® wireless communication adapter, and an infrared (IR) communication port.

The computer system 1100 may also include one or more input device(s) 1111 and one or more output device(s) 1113. Some examples of the one or more input device(s) 1111 include a keyboard, mouse, microphone, remote control device, button, joystick, trackball, touchpad, and light pen. Some examples of the one or more output device(s) 1113 include a speaker and a printer. A specific type of output device that is typically included in a computer system 1100 is a display device 1115. The display device 1115 used with implementations disclosed herein may utilize any suitable image projection technology, such as liquid crystal display (LCD), light-emitting diode (LED), gas plasma, electroluminescence, or the like. A display controller 1117 may also be provided to convert data 1107 stored in the memory 1103 into text, graphics, and/or moving images (as appropriate) shown on the display device 1115.

The various components of the computer system 1100 may be coupled together by one or more buses, which may include one or more of a power bus, a control signal bus, a status signal bus, a data bus, other similar components, or combinations thereof. For clarity, the various buses are illustrated in FIG. 11 as a bus system 1119.

Those skilled in the art will appreciate that the above-described componentry is merely one example of a hardware configuration, as the computer system 1100 may include any type of hardware components, including any accompanying firmware or software, for performing the disclosed implementations. The computer system 1100 may also be implemented in part or in whole by electronic circuit components or processors, such as application-specific integrated circuits (ASICs) or field-programmable gate arrays (FPGAs).

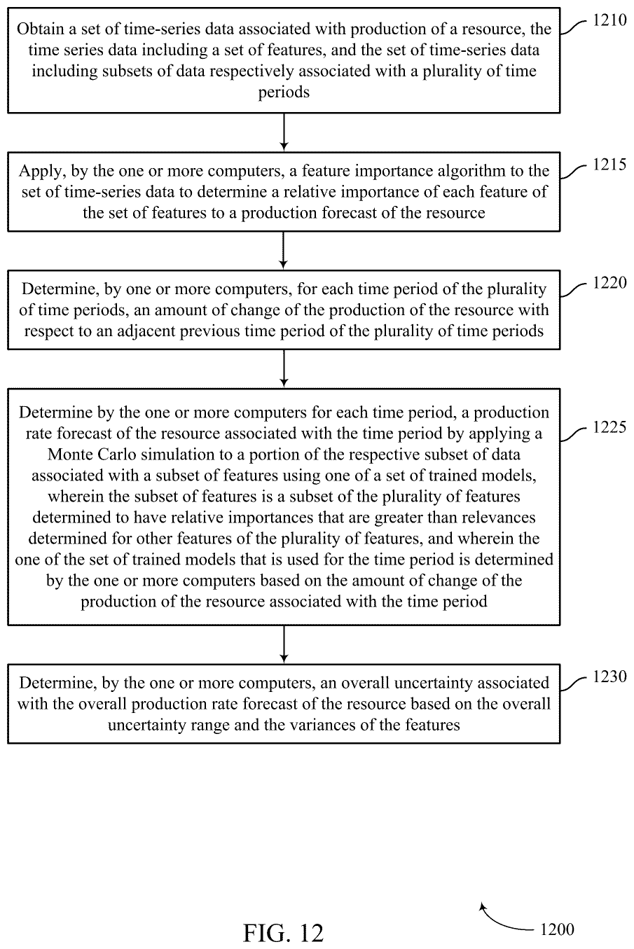

FIG. 12 depicts a series of acts in a computer-implemented method 1200 for determining a production rate forecast of a resource according to at least one embodiment. The method may be for protecting resources associated with petroleum-industry operations. Alternative implementations may omit, add to, reorder, and/or modify any of the acts shown. The operations of method 1200 may be implemented by a processing system or its components as described herein. For example, the operations of method 1200 may be performed by a processing system as described with reference to FIG. 11. Alternatively, a computer-readable medium may include instructions that, when executed by a processing system with a processor, cause the processing system to perform the acts of FIG. 12

At act 1210, the method may include obtaining a set of time-series data associated with production of a resource, the set of time-series data including a plurality of features, and the set of time-series data including subsets of data respectively associated with a plurality of time periods. The operations of act 1210 may be performed in accordance with examples as disclosed herein.

At act 1215, the method may include applying, by one or more computers, a feature importance algorithm to the set of time-series data to determine a relative importance of each feature of the set of features to a production forecast of the resource. The operations of act 1215 may be performed in accordance with examples as disclosed herein.

At act 1220, the method may include determining, by the one or more computers, for each time period of the plurality of time periods, an amount of change of the production of the resource with respect to an adjacent previous time period of the plurality of time periods. The operations of act 1220 may be performed in accordance with examples as disclosed herein.

At act 1225, the method may include determining, by the one or more computers for each time period, a production rate forecast of the resource associated with the time period by applying a Monte Carlo simulation to a portion of the respective subset of data associated with a subset of features using one of a set of trained models, wherein the subset of features is a subset of the plurality of features determined to have relative importances that are greater than relevances determined for other features of the plurality of features, and wherein the one of the set of trained models that is used for the time period is determined by the one or more computers based on the amount of change of the production of the resource associated with the time period. The operations of act 1225 may be performed in accordance with examples as disclosed herein.

At act 1230, the method may include determining, by the one or more computers, an overall production rate forecast of the resource and an overall uncertainty based on the production rate forecasts of the resource associated with each time period. The operations of act 1230 may be performed in accordance with examples as disclosed herein.

In some examples, an apparatus as described herein may perform a method such as the method 1200. The apparatus may include, features, circuitry, logic, means, or instructions (e.g., a non-transitory computer-readable medium storing instructions executable by a processor) for obtaining a set of time-series data associated with production of a resource, the set of time-series data including a plurality of features, and the set of time-series data including subsets of data respectively associated with a plurality of time periods; applying, by one or more computers, a feature importance algorithm to the set of time-series data to determine a relative importance of each feature of the set of features to a production forecast of the resource; determining, by the one or more computers, for each time period of the plurality of time periods, an amount of change of the production of the resource with respect to an adjacent previous time period of the plurality of time periods; determining, by the one or more computers for each time period, a production rate forecast of the resource associated with the time period by applying a Monte Carlo simulation to a portion of the respective subset of data associated with a subset of features using one of a set of trained models, wherein the subset of features is a subset of the plurality of features determined to have relative importances that are greater than relevances determined for other features of the plurality of features, and wherein the one of the set of trained models that is used for the time period is determined by the one or more computers based on the amount of change of the production of the resource associated with the time period; and determining, by the one or more computers, an overall production rate forecast of the resource and an overall uncertainty based on the production rate forecasts of the resource associated with each time period.

In some examples of the method 1200 and the apparatus described herein, the feature importance algorithm may be a Shapley Additive explanations (SHAP) algorithm.

Some examples of the method 1200 and the apparatus described herein may further include operations, features, circuitry, logic, means, or instructions for determining, for each time period, one of a set of regimes based on the amount of change of the production of the resource associated with the time period, wherein the trained model used for each time period is based on the regime associated with the time period.

In some examples of the method 1200 and the apparatus described herein, the set of regimes may include a first regime associated with time periods in which the amount of change of the production of the resource has risen more than a first threshold, a second regime associated with time periods in which the amount of change of the production of the resource has fallen more than a second threshold, and a third regime associated with time periods in which the amount of change of the production of the resource has not raised more than the first threshold nor fallen more than the second threshold.

In some examples of the method 1200 and the apparatus described herein, the trained model used for each time period may be a SARIMA model or an XGBoost model, based on the amount of change of the production of the resource associated with the time period.

In some examples of the method 1200 and the apparatus described herein, if the amount of change of the production of the resource satisfies a threshold, the trained model is the XGBoost model and if the amount of change of the production of the resource fails to satisfy the threshold, the trained model is the SARIMA model.

In some examples of the method 1200 and the apparatus described herein, applying the feature importance algorithm to the set of time-series data may include applying, for each time period, the one of the set of trained models to the respective subset of data used with the Monte Carlo simulation for the time period.

In some examples of the method 1200 and the apparatus described herein, determining the overall uncertainty may include determining, by the one or more computers, an unweighted contribution associated with the subset of features; determining, by the one or more computers, a weighted contribution associated with the subset of features; and determining, by the one or more computers, a dynamic contribution associated with the subset of features using variances determined by the feature importance algorithm.

In some examples of the method 1200 and the apparatus described herein, the plurality of time periods may include a plurality of hour time periods associated with a 24-hour day.

Some examples of the method 1200 and the apparatus described herein may further include operations, features, circuitry, logic, means, or instructions for performing the method daily.

Some examples of the method 1200 and the apparatus described herein may further include operations, features, circuitry, logic, means, or instructions for selecting the features of the plurality of features to include in the subset of features based on the determined overall relative importance of each feature of the plurality of features.

Some examples of the method 1200 and the apparatus described herein may further include operations, features, circuitry, logic, means, or instructions for generating a list of the features and associated overall relative importances.

In some examples of the method 1200 and the apparatus described herein, the set of time-series data may include raw well performance time-series data.

In some examples of the method 1200 and the apparatus described herein, the trained model used for the time period may be based on the amount of change of the production of the resource compared to a threshold.

In some examples of the method 1200 and the apparatus described herein, the trained model used for the time period may be a first trained model if the amount of change of the production of the resource satisfies the threshold and the trained model used for the time period may be a second trained model if the amount of change of the production of the resource fails to satisfy the threshold.

In some examples of the method 1200 and the apparatus described herein, the set of features may include one or more of: average downhole pressure, average choke size, average downhole temperature, average annulus pressure, or average wellhead pressure.

In some examples of the method 900 and the apparatus described herein, the resource may include carbon dioxide for carbon sequestration.

In some examples of the method 1200 and the apparatus described herein, the resource may include a gas.

In some examples of the method 1200 and the apparatus described herein, the resource may include a petroleum resource.

In some examples of the method 1200 and the apparatus described herein, the set of time-series data may include a first subset of data associated with a first time period of the plurality of time periods and a second subset of data associated with a second time period of the plurality of time periods.

In some examples of the method 1200 and the apparatus described herein, determining, for each time period, an amount of change of the production of the resource with respect to an adjacent previous time period may include determining, for the first time period that the amount of change of the resource is greater than a threshold; and determining, for the second time period that the amount of change of the resource is not greater than the threshold.

In some examples of the method 1200 and the apparatus described herein, determining, for each time period, a probabilistic distribution of production rate forecasts of the resource associated with the time period by applying a Monte Carlo simulation to a portion of the respective subset of data using one of a set of trained models may include determining a probabilistic distribution of production rate forecasts of the resource associated with the first time period by applying a Monte Carlo simulation to a portion of the respective first subset of data using a first trained model of the set of trained models based on the amount of change of the production of the resource associated with the first time period being greater than the threshold; and determining a probabilistic distribution of production rate forecasts of the resource associated with the second time period by applying a Monte Carlo simulation to a portion of the respective second subset of data using a second trained model of the set of trained models based on the amount of change of the production of the resource associated with the second time period being less than the threshold.

In some examples of the method 1200 and the apparatus described herein, the feature importance algorithm may determine a variance of each feature. In some examples of the method 1200 and the apparatus described herein, the overall uncertainty may be based at least in part on the variances of the features.

In some examples of the method 1200 and the apparatus described herein, the feature importance algorithm may be applied to each time period and the relative importance of each feature of the set of features to the production forecast of the resource may be based on the relative importances of the features determined for each time period.

In some examples of the method 1200 and the apparatus described herein, applying the Monte Carlo simulation to the portion of the respective subset of data associated with the subset of features may generate a probabilistic distribution of production rate forecasts associated with each time period. In some examples of the method 1200 and the apparatus described herein, the production rate forecast and uncertainty associated with the time period may be determined based on the probabilistic distribution.

Some examples of the method 1200 and the apparatus described herein may further include operations, features, circuitry, logic, means, or instructions for determining an overall probabilistic rate forecast based on the probabilistic rate forecasts of the time periods, wherein the overall production rate forecast and uncertainty is determined based on overall probabilistic rate forecast.

Some examples of the method 1200 and the apparatus described herein may further include operations, features, circuitry, logic, means, or instructions for determining an overall uncertainty range, wherein the overall uncertainty is determined based on the overall uncertainty range.

In some examples of the method 1200 and the apparatus described herein, the feature importance algorithm may generate the subset of features.

To evaluate the effectiveness of the resource production forecasting system described herein, a publicly available dataset was used, which provided a comprehensive collection of production and operational data for offshore wells. The performance of the resource production forecasting system was benchmarked against multiple baseline models, leveraging both deterministic and probabilistic forecasting techniques to assess its predictive accuracy and uncertainty quantification.

The dataset included detailed operational metrics such as average downhole pressure, average downhole temperature, average tubing pressure, and average choke size pressure, along with production metrics including daily bore oil, bore gas, and bore water volumes. The target variable used for forecasting was the bore oil volume, representing daily oil production. Features such as on-stream hours, average downhole pressure, and average choke size pressure were selected as predictors based on their relevance to oil production dynamics. The data was filtered from January 2010 onwards to focus on relevant production periods, to ensure consistency in operational behavior. Missing and invalid values were handled by removing rows that had missing or invalid values in key features. To facilitate model training and improve numerical stability, the target variable (the bore oil volume) was normalized using Z-score normalization.

As discussed herein, one aspect of at least one embodiment of the resource production forecasting system is the identification of production regimes. For the evaluation, the production regimes were categorized as spike, dip, and steady periods. A spike was defined as a sharp increase in production (≥20% change), a dip was characterized by a sharp decrease (≤−20% change), while a steady period exhibited minor or no significant change.

To assess the forecasting performance, the resource production forecasting system was compared against several baseline models. The Random Forest Regressor, an ensemble learning method utilizing decision trees, was included for its ability to incorporate feature importance in regression. A Long Short-Term Memory (LSTM) network, a deep learning model designed for sequential data, was employed to capture long-term dependencies in production trends. Bayesian Linear Regression, a probabilistic approach estimating posterior distributions for model parameters, was incorporated to provide direct uncertainty quantification. In contrast, the resource production forecasting system integrated XGBoost for predicting spike and dip regimes, SARIMA for steady-state forecasting, and Monte Carlo simulations to generate probabilistic forecasts and quantify uncertainty, as discussed herein with respect to at least one embodiment of the resource production forecasting system.

The evaluation employed standard accuracy metrics, including Mean Absolute Error (MAE) and Root Mean Squared Error (RMSE), to assess the predictive performance of each model. Additionally, Monte Carlo simulations were used to compute probabilistic thresholds, namely P10, P50, and P90, which represent optimistic, median, and pessimistic forecast scenarios, respectively, as discussed herein. The range between the P90 and P10 values defined the forecast uncertainty, providing a quantifiable measure of prediction variability.

To ensure robustness, model validation was performed using a temporal split, allocating 80% of the data for training and 20% for testing. Regime-specific validation was conducted separately for each category to account for distinct production behaviors. Further analysis included residual distribution assessments to identify systematic biases, SHAP summary plots to interpret feature contributions, and visualization of forecast intervals to illustrate uncertainty ranges across regimes. The final results indicated that the resource production forecasting system effectively captured production fluctuations, offering improved accuracy over traditional models. The inclusion of Monte Carlo simulations enhanced risk assessment by quantifying forecast uncertainty, thereby providing actionable insights for informed decision-making in oil production management.

The results obtained from the experimental setup demonstrated the effectiveness of the resource production forecasting system in forecasting oil production under different regimes while quantifying uncertainty. The evaluation considered both individual regime performance and overall forecasting accuracy. The results are categorized into two subsections: individual forecasting performance across regimes and a comparative assessment against benchmark models.

### Regime-Specific Forecasting Performance

The predictive accuracy of the resource production forecasting system was evaluated separately for the spike, dip, and steady-state regimes. The results indicate that the resource production forecasting system successfully captured the variations within each production phase. The forecasting performance was measured using MAE and RMSE:

TABLE 1

| Regime | MAE | RMSE |
|---|---|---|
| Spike | 0.4227 | 0.7582 |
| Dip | 0.2590 | 0.4554 |
| Steady | 0.1332 | 0.1925 |

The steady regime demonstrated the lowest error values due to the relative stability in production trends, whereas the spike and dip regimes, characterized by abrupt changes, exhibited higher error metrics. Despite these challenges, the integration of SHAP-based feature analysis and Monte Carlo simulations significantly improved a model's capacity to address the variability inherent in these regimes.

Monte Carlo simulations were performed to estimate the uncertainty associated with the forecasts, contributing significantly to risk assessment and decision-making in dynamic regimes. By simulating multiple scenarios, the resource production forecasting system captures the probabilistic range of outcomes, enabling stakeholders to evaluate production risks under various conditions. This approach allows for informed decision-making, particularly in volatile production phases such as spike and dip regimes, where higher variability necessitates a comprehensive uncertainty quantification framework. The uncertainty range, defined by the P90 and P10 thresholds, is wider in spike and dip regimes, reflecting the higher variability and unpredictability. Conversely, the steady regime shows a narrower uncertainty range, indicative of greater forecast reliability.

Overall, the uncertainty ranges using the resource production forecasting system aligned with regime-specific behaviors. For spike and dip regimes, wider uncertainty bounds were determined, which reflected a model's sensitivity to abrupt production changes and variability. In contrast, for steady regimes, narrower bounds were determined, illustrating greater confidence in predictions due to the stable nature of production trends during those periods.

### Feature Importance Analysis

SHAP summary plots provided insights into the contribution of each feature across the three regimes. The average choke size (AVG_CHOKE_SIZE_P) and the average downhole pressure (AVG_DOWNHOLE_PRESSURE) were the most influential features in the spike regime, reflecting their roles in abrupt production changes. For the dip regime, the average downhole pressure (AVG_DOWNHOLE_PRESSURE) and average DP tubing (AVG_DP_TUBING) dominated, reflecting their impacts during production declines. For the steady regime, a balanced contribution from multiple features occurred, with less pronounced dominance by any single predictor.

The analysis highlighted the significance of predictors such as the average downhole pressure and the average choke size in influencing production trends. Notably, in the spike regime, sharp variations in feature influence suggested rapid operational adjustments, whereas the dip regime demonstrated a more gradual shift in feature relevance. The steady regime, in contrast, maintained relatively stable feature contributions, reinforcing its lower forecasting uncertainty. These insights bridge the gap between predictive accuracy and interpretability, allowing for more data-driven decision-making in oil production forecasting. The analysis highlighted the significance of predictors such as the average downhole pressure and the average choke size in influencing production trends. SHAP plots revealed temporal dynamics in feature relative importance, enabling interpretable predictions for each regime.

### Comparative Performance Analysis—AI Models

The performance of the resource production forecasting system was benchmarked against alternative models, including Random Forest Regressor, LSTM, and Bayesian Linear Regression. The results in terms of MAE and RMSE are as follows:

TABLE 2

| Model | MAE | RMSE |
|---|---|---|
| Resource Production Forecasting System | 0.549 | 0.751 |
| Random Forest Regressor | 0.612 | 0.899 |
| LSTM | 0.628 | 0.915 |
| Bayesian Linear Regression | 0.678 | 0.987 |

The resource production forecasting system consistently outperformed the alternative models in both accuracy and uncertainty quantification. While Random Forest Regressor and LSTM models provided acceptable accuracy, their lack of explicit uncertainty measures limits their utility in risk-aware decision-making. Bayesian Linear Regression, despite offering probabilistic forecasts, underperformed in predictive accuracy compared to the resource production forecasting system.

The superior performance of the resource production forecasting system may be attributed to the integration of SHAP-based feature importance analysis and Monte Carlo simulations for uncertainty quantification. Unlike deterministic models, which solely predict point estimates, the resource production forecasting system provides a probabilistic range of outcomes, enabling robust decision-making in dynamic production environments. The SHAP-based feature analysis enhances interpretability by identifying key drivers of oil production fluctuations, while Monte Carlo simulations account for variability in feature behavior, improving forecast reliability in volatile regimes. This combination allows for more effective risk assessment, particularly in spike and dip regimes where production anomalies are common.

The experimental results validated the ability of the resource production forecasting system to accurately forecast resource production across dynamic regimes while providing actionable uncertainty estimates. By integrating regime-specific modeling, SHAP-based feature analysis, and Monte Carlo simulations, the resource production forecasting system offers a comprehensive approach to capturing variability in production trends. The combination of these techniques enables not only improved predictive accuracy but also a robust quantification of uncertainty, allowing for risk-aware decision-making in volatile operational environments.

In comparison with traditional forecasting methods, the resource production forecasting system demonstrates superior performance. It consistently produced the lowest MAE and RMSE. The results highlight that the ability of the resource production forecasting system to integrate complex production patterns leads to more accurate and reliable forecasts compared to more simplistic approaches, such as Hubbert's Curve and DCA. These traditional models, although widely used, are less capable of handling complexities inherent in reservoir production, leading to higher error rates.

Further, the resource production forecasting system ‘excels in providing a smoother forecast that aligns closely with actual production data, a feature not observed in Hubbert's Curve and DCA models. The smoothing aspect of the resource production forecasting system enhances its practical value, allowing forecasts to reflect realistic production trends and variations over time, while also minimizing volatility in predictions.

The superior performance of the resource production forecasting system approach over benchmark models further emphasizes the benefits of incorporating interpretability and probabilistic modeling in resource production forecasting. By combining regime-specific modeling, SHAP-based feature analysis, and Monte Carlo simulations, the approach of the resource production forecasting system addresses many challenges in oil production forecasting, offering a robust and interpretable solution for industry applications. This enhanced forecasting ability, along with uncertainty quantification, positions the resource production forecasting system as a reliable tool for risk-aware decision-making in many industries, such as the oil and gas industry.

In one or more embodiments, a method of forecasting production associated with a resource includes: obtaining a set of time-series data associated with production of a resource, the set of time-series data including a plurality of features, the set of time-series data including subsets of data respectively associated with a plurality of time periods; applying, by one or more computers, a feature importance algorithm to the set of time-series data to determine a relevance of each feature of the plurality of features to a production forecast of the resource and to generate a subset of features that consists of features of the plurality of features determined to have relevances that are greater than relevances determined for other features of the plurality of features; and applying, by the one or more computers, a Monte Carlo simulation to a portion of the set of time-series data associated with the subset of features to determine a production rate forecast of the resource and an associated uncertainty.

In some embodiments, the feature importance algorithm is a Shapley Additive explanations (SHAP) algorithm. Applying the Monte Carlo simulation, in some embodiments, includes applying, by the one or more computers for each time period of the plurality of time periods, a Monte Carlo simulation to a portion of the subset of data respectively associated with the time period. In some embodiments, the uncertainty is based on information determined from applying the feature importance algorithm to the set of time-series data.

In one or more embodiments, a method of forecasting production associated with a resource, includes: obtaining a set of time-series data associated with production of a resource, the set of time-series data including subsets of data respectively associated with a plurality of time periods; determining, by one or more computers for each time period of the plurality of time periods, an amount of change of the production of the resource with respect to an adjacent previous time period of the plurality of time periods; applying, by the one or more computers for each time period, one of a set of trained models to the respective subset of data associated with the time period to determine a production rate forecast of the resource associated with the time period, wherein the one of the set of trained models that is applied to the respective subset of data is determined by the one or more computers based on the amount of change of the production of the resource associated with the time period; and determining, by the one or more computers, an overall production rate forecast of the resource based on the production rate forecasts of the resource associated with each time period.

In some embodiments, the set of trained models includes a SARIMA model and an XGBoost model. A first model, in some embodiments, is applied to the respective subset of data when the amount of change of the production of the resource associated with the time period satisfies a threshold and a second model that is different than the first model is applied to the respective subset of data when the amount of change fails to satisfy the threshold. In some embodiments, determining, for each time period, an amount of change of the production of the resource with respect to an adjacent previous time period includes: determining, for a first time period, a first amount of change of the production of the resource with respect to an adjacent first previous time period; and determining, for a second time period, a second amount of change of the production of the resource with respect to an adjacent second previous time period; and wherein applying, for each time period, one of a set of trained models to the respective subset of data associated with the time period includes: applying, for a first time period, a first trained model to the respective subset of data associated with the first time period based on the first amount of change of the production of the resource; and applying, for a second time period, a second trained model that is different than the first model to the respective subset of data associated with the second time period based on the second amount of change of the production of the resource.

In one or more embodiments, the method includes determining, for each time period, one of a set of regimes based on the amount of change of the production of the resource associated with the time period, wherein the one of the set of trained models that is applied to the respective subset of data associated with the time period is based on the regime associated with the time period. In some embodiments, a first model is applied to the respective subset of data when the time period is associated with a first regime of the set of regimes and a second model that is different than the first model is applied to the respective subset of data when the time period is associated with a second regime of the set of regimes. A third model, in some embodiments, is applied to the respective subset of data when the time period is associated with a third regime of the set of regimes. In some embodiments, the set of regimes includes: a first regime associated with time periods in which the amount of change of the production of the resource has risen more than a first threshold; a second regime associated with time periods in which the amount of change of the production of the resource has fallen more than a second threshold; and a third regime associated with time periods in which the amount of change of the production of the resource has not raised more than the first threshold nor fallen more than the second threshold.

In one or more embodiments, a method of forecasting production associated with a resource, includes: obtaining a set of time-series data associated with production of a resource, the time-series data including a set of features, and the set of time-series data including subsets of data respectively associated with a plurality of time periods; determining, by one or more computers, for each time period of the plurality of time periods, an amount of change of the production of the resource with respect to an adjacent previous time period; applying, by the one or more computers, a feature importance algorithm to the set of time-series data to determine, for each time period, a relative importance and a variance of each feature of the set of features to a production forecast of the resource; determining, by the one or more computers, an overall relative importance of each feature based on the relative importance of each feature determined for each time period; determining, by the one or more computers for each time period, a probabilistic distribution of production rate forecasts of the resource associated with the time period by applying a Monte Carlo simulation to a portion of the respective subset of data associated with a subset of features using one of a set of trained models, wherein the subset of features is a subset of the plurality of features determined to have relative importances that are greater than relevances determined for other features of the plurality of features, and wherein the one of the set of trained models that is used for the time period is determined by the one or more computers based on the amount of change of the production of the resource associated with the time period; determining, by the one or more computers, an overall probabilistic distribution of production rate forecasts of the resource based on the probabilistic distribution of production rate forecasts of the resource associated with each time period; determining, by the one or more computers, an overall production rate forecast of the resource and an overall uncertainty range based on the production rate forecasts of the resource associated with each time period; and determining, by the one or more computers, an overall uncertainty associated with the overall production rate forecast of the resource based on the overall uncertainty range and the variances of the features.

In some embodiments, the feature importance algorithm is a Shapley Additive explanations (SHAP) algorithm. The method includes, in some embodiments, determining, for each time period, one of a set of regimes based on the amount of change of the production of the resource associated with the time period, wherein the trained model used for each time period is based on the regime associated with the time period. The set of regimes, in some embodiments, includes: a first regime associated with time periods in which the amount of change of the production of the resource has risen more than a first threshold; a second regime associated with time periods in which the amount of change of the production of the resource has fallen more than a second threshold; and a third regime associated with time periods in which the amount of change of the production of the resource has not raised more than the first threshold nor fallen more than the second threshold.

In some embodiments, the trained model used for each time period is a SARIMA model or an XGBoost model, based on the amount of change of the production of the resource associated with the time period. If the amount of change of the production of the resource satisfies a threshold, the trained model, in some embodiments, is the XGBoost model and if the amount of change of the production of the resource fails to satisfy the threshold, the trained model is the SARIMA model.

In some embodiments, applying the feature importance algorithm to the set of time-series data includes applying, for each time period, the one of the set of trained models to the respective subset of data used with the Monte Carlo simulation for the time period. Determining the overall uncertainty, in some embodiments, includes: determining, by the one or more computers, an unweighted contribution associated with the subset of features; determining, by the one or more computers, a weighted contribution associated with the subset of features; and determining, by the one or more computers, a dynamic contribution associated with the subset of features using the determined variances. In some embodiments, the plurality of time periods includes a plurality of hour time periods associated with a 24-hour day. The method, in some embodiments, is performed on a daily cycle. In some embodiments, selecting the features of the plurality of features to include in the subset of features based on the determined overall relative importance of each feature of the plurality of features. The method, in some embodiments, includes generating a list of the features and associated overall relative importances. In some embodiments, the set of time-series data includes raw well performance time-series data.

The trained model used for the time period, in some embodiments, is based on the amount of change of the production of the resource compared to a threshold. In some embodiments, the trained model used for the time period is a first trained model if the amount of change of the production of the resource satisfies the threshold and the trained model used for the time period is a second trained model if the amount of change of the production of the resource fails to satisfy the threshold.

In some embodiments, the set of features includes one or more of: average downhole pressure, average choke size, average downhole temperature, average annulus pressure, or average wellhead pressure. The resource, in some embodiments, includes carbon dioxide for carbon sequestration. In some embodiments, the resource includes a gas. The resource, in some embodiments, includes a petroleum resource.

In at least one wherein the set of time-series data includes a first subset of data associated with a first time period of the plurality of time periods and a second subset of data associated with a second time period of the plurality of time periods; wherein determining, for each time period, an amount of change of the production of the resource with respect to an adjacent previous time period includes: determining, for the first time period that the amount of change of the resource is greater than a threshold; and determining, for the second time period that the amount of change of the resource is not greater than the threshold; and wherein determining, for each time period, a probabilistic distribution of production rate forecasts of the resource associated with the time period by applying a Monte Carlo simulation to a portion of the respective subset of data using one of a set of trained models includes: determining a probabilistic distribution of production rate forecasts of the resource associated with the first time period by applying a Monte Carlo simulation to a portion of the respective first subset of data using a first trained model of the set of trained models based on the amount of change of the production of the resource associated with the first time period being greater than the threshold; and determining a probabilistic distribution of production rate forecasts of the resource associated with the second time period by applying a Monte Carlo simulation to a portion of the respective second subset of data using a second trained model of the set of trained models based on the amount of change of the production of the resource associated with the second time period being less than the threshold.

The techniques described herein may be implemented in hardware, software, firmware, or any combination thereof, unless specifically described as being implemented in a specific manner. Any features described as modules, components, or the like may also be implemented together in an integrated logic device or separately as discrete but interoperable logic devices. If implemented in software, the techniques may be realized at least in part by a non-transitory processor-readable storage medium including instructions that, when executed by at least one processor, perform one or more of the methods (e.g., computer-implemented methods) described herein. The instructions may be organized into routines, programs, objects, components, data structures, etc., which may perform particular tasks and/or implement particular data types, and which may be combined or distributed as desired in various embodiments.

Further, upon reaching various computer system components, program code in the form of computer-executable instructions or data structures can be transferred automatically or manually from transmission media to non-transitory computer-readable storage media (or vice versa). For example, computer executable instructions or data structures received over a network or data link can be buffered in memory (e.g., RAM) within a network interface module (NIC), and then eventually transferred to computer system RAM and/or to less volatile non-transitory computer-readable storage media at a computer system. Thus, it should be understood that non-transitory computer-readable storage media can be included in computer system components that also (or even primarily) utilize transmission media.

One or more specific embodiments of the present disclosure are described herein. These described embodiments are examples of the presently disclosed techniques. Additionally, in an effort to provide a concise description of these embodiments, not all features of an actual embodiment may be described in the specification. It should be appreciated that in the development of any such actual implementation, as in any engineering or design project, numerous embodiment-specific decisions will be made to achieve the developers' specific goals, such as compliance with system-related and business-related constraints, which may vary from one embodiment to another. Moreover, it should be appreciated that such a development effort might be complex and time consuming, but would nevertheless be a routine undertaking of design, fabrication, and manufacture for those of ordinary skill having the benefit of this disclosure.

Additionally, it should be understood that references to “one embodiment” or “an embodiment” of the present disclosure are not intended to be interpreted as excluding the existence of additional embodiments that also incorporate the recited features. For example, any element described in relation to an embodiment herein may be combinable with any element of any other embodiment described herein. Numbers, percentages, ratios, or other values stated herein are intended to include that value, and also other values that are “about” or “approximately” the stated value, as would be appreciated by one of ordinary skill in the art encompassed by embodiments of the present disclosure. A stated value should therefore be interpreted broadly enough to encompass values that are at least close enough to the stated value to perform a desired function or achieve a desired result. The stated values include at least the variation to be expected in a suitable manufacturing or production process, and may include values that are within 5%, within 1%, within 0.1%, or within 0.01% of a stated value.

A person having ordinary skill in the art should realize in view of the present disclosure that equivalent constructions do not depart from the spirit and scope of the present disclosure, and that various changes, substitutions, and alterations may be made to embodiments disclosed herein without departing from the spirit and scope of the present disclosure. Equivalent constructions, including functional “means-plus-function” clauses are intended to cover the structures described herein as performing the recited function, including both structural equivalents that operate in the same manner, and equivalent structures that provide the same function. It is the express intention of the applicant not to invoke means-plus-function or other functional claiming for any claim except for those in which the words ‘means for’ appear together with an associated function. Each addition, deletion, and modification to the embodiments that falls within the meaning and scope of the claims is to be embraced by the claims.

The terms “approximately,” “about,” and “substantially” as used herein represent an amount close to the stated amount that is within standard manufacturing or process tolerances, or which still performs a desired function or achieves a desired result. For example, the terms “approximately,” “about,” and “substantially” may refer to an amount that is within less than 5% of, within less than 1% of, within less than 0.1% of, and within less than 0.01% of a stated amount. Further, it should be understood that any directions or reference frames in the preceding description are merely relative directions or movements. For example, any references to “up” and “down” or “above” or “below” are merely descriptive of the relative position or movement of the related elements.

The present disclosure may be embodied in other specific forms without departing from its spirit or characteristics. The described embodiments are to be considered as illustrative and not restrictive. The scope of the disclosure is, therefore, indicated by the appended claims rather than by the foregoing description. Changes that come within the meaning and range of equivalency of the claims are to be embraced within their scope.

What is claimed is:

1. A method of forecasting production associated with a resource, comprising:
obtaining a set of time-series data associated with production of a resource, the set of time-series data including a plurality of features, the set of time-series data including subsets of data respectively associated with a plurality of time periods;
applying, by one or more computers, a feature importance algorithm to the set of time-series data to determine a relevance of each feature of the plurality of features to a production forecast of the resource and to generate a subset of features that consists of features of the plurality of features determined to have relevances that are greater than relevances determined for other features of the plurality of features; and
applying, by the one or more computers, a Monte Carlo simulation to a portion of the set of time-series data associated with the subset of features to determine a production rate forecast of the resource and an associated uncertainty.

2. The method of claim 1, wherein the feature importance algorithm is a Shapley Additive explanations (SHAP) algorithm.

3. The method of claim 1, wherein applying the Monte Carlo simulation includes applying, by the one or more computers for each time period of the plurality of time periods, a Monte Carlo simulation to a portion of the subset of data respectively associated with the time period.

4. The method of claim 1, wherein the uncertainty is based on information determined from applying the feature importance algorithm to the set of time-series data.

5. A method of forecasting production associated with a resource, comprising:
obtaining a set of time-series data associated with production of a resource, the set of time-series data including subsets of data respectively associated with a plurality of time periods;
determining, by one or more computers for each time period of the plurality of time periods, an amount of change of the production of the resource with respect to an adjacent previous time period of the plurality of time periods;
applying, by the one or more computers for each time period, one of a set of trained models to the respective subset of data associated with the time period to determine a production rate forecast of the resource associated with the time period, wherein the one of the set of trained models that is applied to the respective subset of data is determined by the one or more computers based on the amount of change of the production of the resource associated with the time period; and
determining, by the one or more computers, an overall production rate forecast of the resource based on the production rate forecasts of the resource associated with each time period.

6. The method of claim 5, wherein the set of trained models includes a SARIMA model and an XGBoost model.

7. The method of claim 5, wherein a first model is applied to the respective subset of data when the amount of change of the production of the resource associated with the time period satisfies a threshold and a second model that is different than the first model is applied to the respective subset of data when the amount of change fails to satisfy the threshold.

8. The method of claim 5, wherein determining, for each time period, an amount of change of the production of the resource with respect to an adjacent previous time period includes:
determining, for a first time period, a first amount of change of the production of the resource with respect to an adjacent first previous time period; and
determining, for a second time period, a second amount of change of the production of the resource with respect to an adjacent second previous time period,
wherein applying, for each time period, one of a set of trained models to the respective subset of data associated with the time period includes:
applying, for a first time period, a first trained model to the respective subset of data associated with the first time period based on the first amount of change of the production of the resource; and
applying, for a second time period, a second trained model that is different than the first model to the respective subset of data associated with the second time period based on the second amount of change of the production of the resource.

9. The method of claim 5, further comprising determining, for each time period, one of a set of regimes based on the amount of change of the production of the resource associated with the time period, wherein the one of the set of trained models that is applied to the respective subset of data associated with the time period is based on the regime associated with the time period.

10. The method of claim 9, wherein a first model is applied to the respective subset of data when the time period is associated with a first regime of the set of regimes and a second model that is different than the first model is applied to the respective subset of data when the time period is associated with a second regime of the set of regimes.

11. The method of claim 9, wherein the set of regimes includes:
a first regime associated with time periods in which the amount of change of the production of the resource has risen more than a first threshold;
a second regime associated with time periods in which the amount of change of the production of the resource has fallen more than a second threshold; and
a third regime associated with time periods in which the amount of change of the production of the resource has not raised more than the first threshold nor fallen more than the second threshold.

12. A method of forecasting production associated with a resource, comprising:
obtaining a set of time-series data associated with production of a resource, the set of time-series data including a plurality of features, and the set of time-series data including subsets of data respectively associated with a plurality of time periods;
applying, by one or more computers, a feature importance algorithm to the set of time-series data to determine a relative importance of each feature of the set of features to a production forecast of the resource;
determining, by the one or more computers, for each time period of the plurality of time periods, an amount of change of the production of the resource with respect to an adjacent previous time period of the plurality of time periods;
determining, by the one or more computers for each time period, a production rate forecast of the resource associated with the time period by applying a Monte Carlo simulation to a portion of the respective subset of data associated with a subset of features using one of a set of trained models, wherein the subset of features is a subset of the plurality of features determined to have relative importances that are greater than relevances determined for other features of the plurality of features, and wherein the one of the set of trained models that is used for the time period is determined by the one or more computers based on the amount of change of the production of the resource associated with the time period; and
determining, by the one or more computers, an overall production rate forecast of the resource and an overall uncertainty based on the production rate forecasts of the resource associated with each time period.

13. The method of claim 12, further comprising determining, for each time period, one of a set of regimes based on the amount of change of the production of the resource associated with the time period, wherein the trained model used for each time period is based on the regime associated with the time period.

14. The method of claim 12, wherein applying the feature importance algorithm to the set of time-series data includes applying, for each time period, the one of the set of trained models to the respective subset of data used with the Monte Carlo simulation for the time period.

15. The method of claim 12, wherein determining the overall uncertainty includes:
determining, by the one or more computers, an unweighted contribution associated with the subset of features;
determining, by the one or more computers, a weighted contribution associated with the subset of features; and
determining, by the one or more computers, a dynamic contribution associated with the subset of features using variances determined by the feature importance algorithm.

16. The method of claim 12, further comprising selecting the features of the plurality of features to include in the subset of features based on the determined overall relative importance of each feature of the plurality of features.

17. The method of claim 12, wherein the set of time-series data includes a first subset of data associated with a first time period of the plurality of time periods and a second subset of data associated with a second time period of the plurality of time periods; and wherein determining, for each time period, a production rate forecast of the resource associated with the time period includes:
applying a Monte Carlo simulation to a portion of the respective first subset of data using a first trained model of the set of trained models based on the amount of change of the production of the resource associated with the first time period being greater than a threshold; and
applying a Monte Carlo simulation to a portion of the respective second subset of data using a second trained model of the set of trained models based on the amount of change of the production of the resource associated with the second time period being less than the threshold.

18. The method of claim 12, wherein the feature importance algorithm is applied to each time period and the relative importance of each feature of the set of features to the production forecast of the resource is based on the relative importances of the features determined for each time period.

19. The method of claim 12, wherein, for each time period, applying the Monte Carlo simulation to the portion of the respective subset of data associated with the subset of features generates a probabilistic distribution of production rate forecasts associated with the time period, and wherein the method further comprises determining an overall probabilistic rate forecast based on the probabilistic rate forecasts of the time periods, and wherein the overall production rate forecast and uncertainty is determined based on overall probabilistic rate forecast.

20. The method of claim 12, further comprising determining an overall uncertainty range, wherein the overall uncertainty is determined based on the overall uncertainty range.
